(19) United States
(12) Patent Application Publication
(10) Pub. No.: US 2025/0380062 A1
(43) Pub. Date: Dec. 11, 2025

(54) VISION SENSOR AND IMAGE PROCESSING DEVICE INCLUDING THE SAME

(71) Applicant: Samsung Electronics Co., Ltd., Suwon-si (KR)

(72) Inventors: Keunjoo Park, Suwon-si (KR); JUNSEOK KIM, Suwon-si (KR); Bongki Son, Suwon-si (KR)

(21) Appl. No.: 19/179,620

(22) Filed: Apr. 15, 2025

(30) Foreign Application Priority Data
Jun. 11, 2024 (KR) 10-2024-0075816

(51) Int. Cl. H04N 25/47; H04N 25/707; H04N 25/766; H04N 25/772; H10F 39/00; H10F 39/18; H10F 39/95

(52) U.S. Cl. CPC H04N 25/47; H04N 25/707; H04N 25/766; H04N 25/772; H10F 39/18; H10F 39/8037; H10F 39/811; H10F 39/95

(57) ABSTRACT

Provided is a vision sensor comprising a first semiconductor die comprising a plurality of photoelectric conversion element groups, and a second semiconductor die comprising a dynamic vision sensor (DVS) pixel circuit and stacked on the first semiconductor die in a copper-to-copper bonding manner, wherein each of the plurality of photoelectric conversion element groups comprises, a first-type photoelectric conversion element configured to output an electrical signal corresponding to an amount of light incident on the first-type photoelectric conversion element, and a plurality of the second-type photoelectric conversion elements, wherein each second-type photoelectric conversion elements is configured to output charges corresponding to an amount of light incident on the second-type photoelectric conversion element, wherein the DVS pixel circuit is configured to output an event signal based on the charges generated by the plurality of second-type photoelectric conversion elements, and wherein, in each the plurality of photoelectric conversion element groups, a total number of second-type photoelectric conversion elements is greater than a total number of first-type photoelectric conversion elements.

### CROSS-REFERENCE TO RELATED APPLICATION

This application is based on and claims ranking under 35 U.S.C. § 119 to Korean Patent Application No. 10-2024-0075816, filed on Jun. 11, 2024, in the Korean Intellectual Property Office, the disclosure of which is incorporated by reference herein in its entirety.

### BACKGROUND

The inventive concept relates to a semiconductor device, and more particularly, to a vision sensor and an image processing device including the vision sensor.

A human-computer interaction (HCI) is manifested at a user interface and operates. Various user interfaces that recognize user input may provide a natural interaction between humans and computers. Various sensors may be used for recognizing the user input.

Image sensor devices are devices which generate electrical signals or digital signals based on incident light from the outside. Recently, event-based sensors, such as dynamic vision sensors (DVSs), which output event signals according to the amount of intensity change of the incident external light, have been developed. The event-based sensors output the event signals by using various components, such as a converter and an amplifier.

### SUMMARY

The inventive concept provides a vision sensor having improved performance and an image processing device including the vision sensor.

According to an aspect of the inventive concept, there is provided a vision sensor comprising a first semiconductor die comprising a plurality of photoelectric conversion element groups, and a second semiconductor die comprising a dynamic vision sensor (DVS) pixel circuit and stacked on the first semiconductor die in a copper-to-copper bonding manner, wherein each of the plurality of photoelectric conversion element groups comprises, a first-type photoelectric conversion element configured to output an electrical signal corresponding to an amount of light incident on the first-type photoelectric conversion element, and a plurality of second-type photoelectric conversion elements, each configured to output charges corresponding to an amount of light incident on the second-type photoelectric conversion element, wherein the DVS pixel circuit is configured to output an event signal based on the charges generated by the plurality of second-type photoelectric conversion elements, and wherein, in each the plurality of photoelectric conversion element groups, a total number of second-type photoelectric conversion elements is greater than a total number of first-type photoelectric conversion elements.

According to another aspect of the inventive concept, there is provided a vision sensor comprising a first semiconductor die comprising a first-type photoelectric conversion element and a second-type photoelectric conversion element; and a second semiconductor die comprising a dynamic vision sensor (DVS) pixel circuit, a selection transistor, and a driving transistor corresponding to the first-type photoelectric conversion element, wherein the first-type photoelectric conversion element is configured to output an electrical signal corresponding to an amount of light incident on the first-type photoelectric conversion element, wherein the second-type photoelectric conversion element is configured to output charges corresponding to an amount of light incident on the second-type photoelectric conversion element, wherein the DVS pixel circuit is configured to output an event signal based on charges generated by the second-type photoelectric conversion element, wherein the first semiconductor die is connected to the second semiconductor die in a copper-to-copper bonding manner, and wherein, a total number of second-type photoelectric conversion elements is greater than a total number of first-type photoelectric conversion elements.

According to another aspect of the inventive concept, there is provided a vision sensor comprising a first semiconductor die comprising a plurality of photoelectric conversion element groups, a second semiconductor die comprising a dynamic vision sensor (DVS) pixel circuit and stacked on the first semiconductor die in a copper-to-copper bonding manner; and a third semiconductor die comprising a complementary metal-oxide semiconductor image sensor (CIS) logic and a DVS logic, wherein each of the plurality of photoelectric conversion element groups comprises a first-type photoelectric conversion element configured to output an electrical signal corresponding to an amount of light incident on the first-type photoelectric conversion element; and a plurality of second-type photoelectric conversion elements, each configured to output charges corresponding to an amount of light incident on the second-type photoelectric conversion element, wherein the DVS pixel circuit is configured to output an event signal based on charges generated by the plurality of second-type photoelectric conversion elements, wherein, in each the plurality of photoelectric conversion element groups, a total number of second-type photoelectric conversion elements is greater than a total number of first-type photoelectric conversion elements, and wherein the third semiconductor die is stacked on the second semiconductor die.

### BRIEF DESCRIPTION OF THE DRAWINGS

Embodiments will be more clearly understood from the following detailed description taken in conjunction with the accompanying drawings in which:

FIG. 1 is a block diagram of an image processing device according to an embodiment;

FIG. 2 is a block diagram of a vision sensor according to an embodiment;

FIG. 3 is a circuit diagram illustrating three second-type photoelectric conversion elements and a dynamic vision sensor (DVS) pixel unit circuit according to an embodiment;

FIG. 4 illustrates a perspective view of a vision sensor including the first-type photoelectric conversion element and the second-type photoelectric conversion elements according to an embodiment;

FIG. 5 is a diagram illustrating an example of a photoelectric conversion element array according to an embodiment of the present disclosure;

FIGS. 6A through 6C are diagrams illustrating an example of a photoelectric conversion element array according to an embodiment of the present disclosure;

FIG. 7 is a diagram illustrating an example of a photoelectric conversion element array according to an embodiment of the present disclosure;

FIG. 8 is a circuit diagram illustrating eight second-type photoelectric conversion elements of the photoelectric conversion element group in FIG. 7, and a DVS pixel unit circuit according to an embodiment;

FIG. 9A is a circuit diagram illustrating four second-type photoelectric conversion elements of the photoelectric conversion element group in FIG. 7, and a first DVS pixel unit circuit according to an embodiment;

FIG. 9B is a circuit diagram illustrating the remaining four second-type photoelectric conversion elements of the photoelectric conversion element group in FIG. 7, and a second DVS pixel unit circuit according to an embodiment;

FIG. 10A is a circuit diagram illustrating three second-type photoelectric conversion elements of the photoelectric conversion element group in FIG. 7, and a first DVS pixel unit circuit according to an embodiment;

FIG. 10B is a circuit diagram illustrating the remaining five second-type photoelectric conversion elements of the photoelectric conversion element group in FIG. 7, and a second DVS pixel unit circuit according to an embodiment; and

FIGS. 11A through 11C are diagrams illustrating an example of a photoelectric conversion element array according to an embodiment of the present disclosure.

### DETAILED DESCRIPTION OF THE EMBODIMENTS

Hereinafter, embodiments of the inventive concept are described clearly and in detail so that one of ordinary skill in the art may easily implement the inventive concept. The example embodiment will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Furthermore, “connected” elements may be “electrically connected” such that an electrical signal can be transferred from one component to the other (although such electrical signal may be attenuated in strength as it is transferred and may be selectively transferred).

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

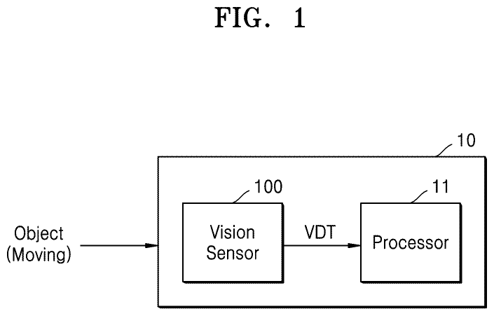

FIG. 1 is a block diagram of an image processing device 10 according to an embodiment.

Referring to FIG. 1, the image processing device 10 may include a vision sensor 100 and a processor 11. The image processing device 10 according to the embodiment may be mounted on electronic equipment having an image or light sensing function.

The vision sensor 100 may include a first pixel PX1 and a second pixel PX2. In the following description, “first pixel PX1” refers to a pixel of a first type, which may also be referred to as a first-type pixel, and not to a specific pixel. Thus, there may be multiple “first pixels” or “first-type pixels”, which are each of the same type. Similarly, “second pixel PX2” refers to a second type of pixel, which may also be referred to as a second-type pixel, and not to a specific pixel. Thus, there may be multiple “second pixels” or “second-type pixels PX2”, which are each of the same type. The vision sensor 100 may include the first pixel PX1 for obtaining image data of an object and the second pixel PX2 for sensing movement of the object. In an embodiment, the first pixel PX1 may include a complementary metal-oxide semiconductor (CMOS) image sensor (CIS) pixel, but embodiments are not limited thereto. The second pixel PX2 may include a dynamic vision sensor (DVS) pixel. For example, the first pixel PX1 may include red-green-blue (RGB) pixels, black-white (BW) pixels, infrared (IR) pixels, or ultraviolet (UV) pixels.

The first pixel PX1 may include photoelectric conversion elements, a transmission transistor, a reset transistor, a driving transistor, and a selection transistor. The first pixel PX1 may further include a dual conversion transistor. However, the scope of the inventive concept is not limited thereto, and the number of transistors and the number of photoelectric conversion elements may increase or decrease depending on implementation. U.S. Patent Publication No. 11,637,983 and U.S. Patent Application Publication No. 2023/0217129 are incorporated herein in their entirety by reference. In an embodiment, the first pixel PX1 may include a first-type photoelectric conversion element.

For example, the first pixel PX1 may include a color pixel. The first pixel PX1 may include a red R pixel, which converts light in a red color spectrum range into a first signal (e.g., an electrical signal). The first pixel PX1 may include a green G pixel, which converts light in a green color spectrum range into an electrical signal. The first pixel PX1 may include a blue B pixel, which converts light in a blue color spectrum range into an electrical signal. The first pixel PX1 may include a cyan pixel, which converts light in a blue color through green color spectrum range into an electrical signal. The first pixel PX1 may include a yellow pixel, which converts light from a green color spectrum range to a red color spectrum range into an electrical signal. The first pixel PX1 may include a magenta pixel, which converts light from a blue color spectrum range to a red color spectrum range into an electrical signal. For example, the first pixel PX1 may include a clear pixel.

The second pixels PX2 may output a second signal (e.g., an event signal) by detecting the intensity change of the light incident on the second pixel PX2. The intensity change of light may be caused by movement of an object photographed by the vision sensor 100, by movement of the vision sensor 100 itself, or by movement of the image processing device 10 itself. The vision sensor 100 may generate event signals periodically or aperiodically, and transmit vision sensor data VDT including the event signals to the processor 11 periodically or aperiodically. The vision sensor data VDT may be generated by using only event signals generated in one frame, or may also be generated by grouping the event signals generated in multiple frames. In an embodiment, the first pixel PX2 may include a plurality of second-type photoelectric conversion elements.

The processor 11 may process the vision sensor data VDT received from the vision sensor 100, and may detect object movement (or object movement on an image recognized by the image processing device 10) based on the event signal in the vision sensor data VDT. The processor 11 may include an application processor or an image signal processor.

Although not illustrated, the processor 11 may include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the processor 11 and storage media or other suitable type of memory where data and/or instructions can be stored. In addition, the processor 11 may include a power source that provides an appropriate alternating current (AC) or direct current (DC) to power one or more components of the processor 11, and a bus that allows communication among the various disclosed components.

Each of the vision sensor 100 and the processor 11 may be implemented as an integrated circuit (IC), or may each be implemented on a semiconductor substrate in a single chip. For example, the vision sensor 100 and the processor 11 may be implemented as separate semiconductor chips. The vision sensor 100 and the processor 11 implemented in separate semiconductor chips may be arranged in one package (PKG). As another example, the vision sensor 100 and the processor 11 implemented on separate semiconductor substrates may be implemented in one chip by using a through-silicon via (TSV) or a copper-to-copper connection.

When a vision sensor includes only the second pixels PX2 but not the first pixels PX1, the vision sensor may not provide sensor data when there is no object movement because an event signal is not generated by the second pixels PX2 when there is no object movement. However, because the vision sensor 100 according to an embodiment includes the first pixel PX1 (for example, the CIS pixel) and the second pixel PX2 (for example, the DVS pixel), image data based on an electric signal corresponding to the amount of light incident on the first pixel PX1 may be provided as vision sensor data, even when there is no object movement. Accordingly, sensor data may be provided regardless of the object movement.

In an embodiment, the vision sensor 100 may operate in any one of first through third modes. In the first mode, the vision sensor 100 may activate only a circuit for processing data generated by the second pixel PX2, and deactivate a circuit for processing data generated by the first pixel PX1 to operate in a low-power mode. In the second mode, the vision sensor 100 may operate by activating all circuits related to data processing of the first pixel PX1 and the second pixel PX2. In the third mode, the vision sensor 100 may repeatedly operate in a manner in which the vision sensor 100 operates in the first mode for L frames or for a first duration, and operates in the second mode for P frames or for a second duration. In this case, L and P may be natural numbers, may have the same or different values, and may also have the same or different values during the first duration and the second duration.

In another embodiment, in the vision sensor 100, when the amount of vision sensor data that is less than a first reference amount is output for a third duration or for T frame units while operating in the first mode, the mode may be automatically switched to the second mode. In the vision sensor 100, when the amount of event signals generated by the second pixel PX2 or the amount of vision sensor data based on event signals is equal to or greater than a second reference amount for a certain duration or for preset frame units while operating in the second mode, the mode may be automatically switched to the first mode. In this case, T may include a natural number that is a value preset by a user setting. In addition, the first reference amount and the second reference amount may also be preset values according to user settings.

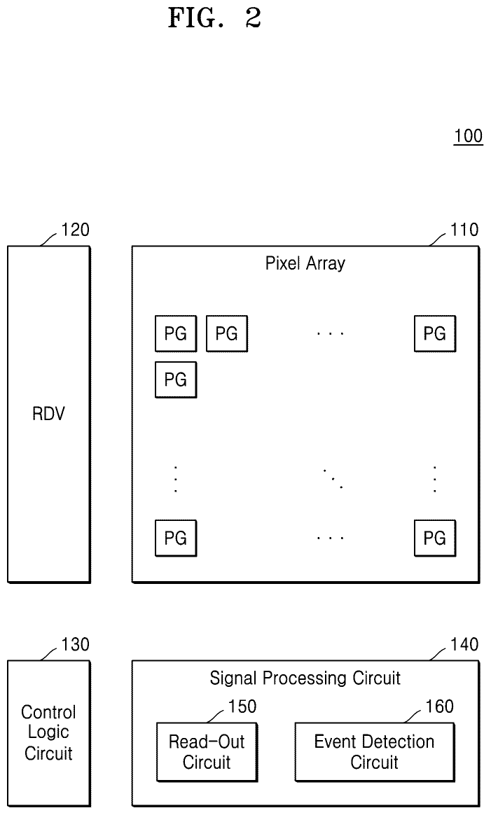

FIG. 2 is a block diagram of a vision sensor 100 according to an embodiment.

Referring to FIGS. 1 and 2, the vision sensor 100 may include a pixel array 110, a row driver (RDV) 120, a control logic circuit 130, and a signal processing circuit 140. The signal processing circuit 140 may include a read-out circuit 150 and an event detection circuit 160.

The pixel array 110 may include a plurality of pixel groups PG arranged in a matrix form (e.g., the pixels of the pixel array 110 may be arranged in pixel groups PG). The pixel groups PG may be arranged in rows and columns in the pixel array 110. Each pixel group PG may include the second pixel PX2 and the first pixel PX1.

The RDV 120 may activate the first pixels PX1 in row units under the control by the control logic circuit 130. The control logic circuit 130 may control the overall operation of the vision sensor 100 based on a control signal provided by the processor 11. The control logic circuit 130 may control each of the RDV 120 and the signal processing circuit 140.

The signal processing circuit 140 may output the vision sensor data VDT by processing the first pixel signal (e.g., electrical signal) output by the first pixels PX1 and the second pixel signal (e.g., event signal) output by the second pixels PX2 of the pixel array 110. The vision sensor data VDT may include image data IDT generated from the first pixel signal and/or event data EDT generated from the second pixel signal.

The signal processing circuit 140 may include the read-out circuit 150 and the event detection circuit 160. The read-out circuit 150 may receive first pixel signals output by each of the plurality of first pixels PX1 included in the pixel array 110, and process the received first pixel signals to generate image data IDT.

In an embodiment, the read-out circuit 150 may include a column decoder (not illustrated), a column driver (not illustrated), a correlated double sampling (CDS) block, an analog-to-digital converter (ADC) block (not illustrated), an output buffer (not illustrated), etc. In an embodiment, the read-out circuit 150 may be deactivated in the first mode, and may be activated in the second mode.

The event detection circuit 160 may receive the second pixel signals output by each of the plurality of second pixels PX2 included in the pixel array 110, and process the received second pixel signals to generate event data EDT. The event detection circuit 160 may include a column address event representation (AER) circuit (not illustrated), a row AER circuit (not illustrated), and an output buffer (not illustrated). In an embodiment, the event detection circuit 160 may be deactivated in the first mode, and may be activated in the second mode.

The vision sensor 100 may use a second pixel signal to detect an event in which the intensity of light changes, determine the type of event (for example, whether it is an event in which the intensity of light increases or decreases), and output a value or data corresponding to the event. An event may correspond mainly to the outline of a moving object.

The second pixel PX2 detecting the event among the plurality of pixels may transmit an event signal indicating that an event of increase or decrease in light intensity has occurred, or a column AER request to the column AER circuit.

The column AER circuit may transmit a response signal to a pixel in response to a column request received from the pixel that has detected the event. The pixel having received the response signal may transmit polarity information of the event to a row AER circuit. The column AER circuit may generate a column address of the pixel, which has detected the event, based on a column request received from the pixel that has detected the event.

The row AER circuit may receive polarity information from the pixel that has detected the event. The row AER circuit may generate a time stamp including information about the time point at which the event occurs, based on the polarity information. For example, the time stamp may be generated by a time stamper (not illustrated) that is provided in the row AER circuit. For example, the time stamper may be implemented by using timeticks generated in units of several to tens of microseconds. The row AER circuit may transmit a reset signal to the second pixel PX2 in which the event has occurred in response to the polarity information. The reset signal may reset the second pixel PX2 in which the event has occurred. Furthermore, the row AER circuit may generate a row address of the second pixel PX2 in which the event has occurred.

An output buffer may generate a packet based on the time stamp, a column address, a row address, and polarity information. The output buffer may add a header notifying the start of the packet to the front end of the packet, and a tail notifying the end of the packet to the rear end of the packet. For example, at least some of a column AER circuit, a row AER circuit, and the output buffer may be referred to as DVS periphery circuits.

As described above, the vision sensor 100 may be a hybrid sensor including both the first pixels PX1 and the second pixels PX2. The vision sensor 100 may generate and output both the image data IDT and the event data EDT. The vision sensor 100 may output only the image data IDT or only the event data EDT according to the first mode and the second mode.

In one embodiment, “first-type photoelectric conversion element” refers to a photoelectric conversion element included in the first pixel PX1, and “second-type photoelectric conversion element” refers to the photoelectric conversion element included in the second pixel PX2.

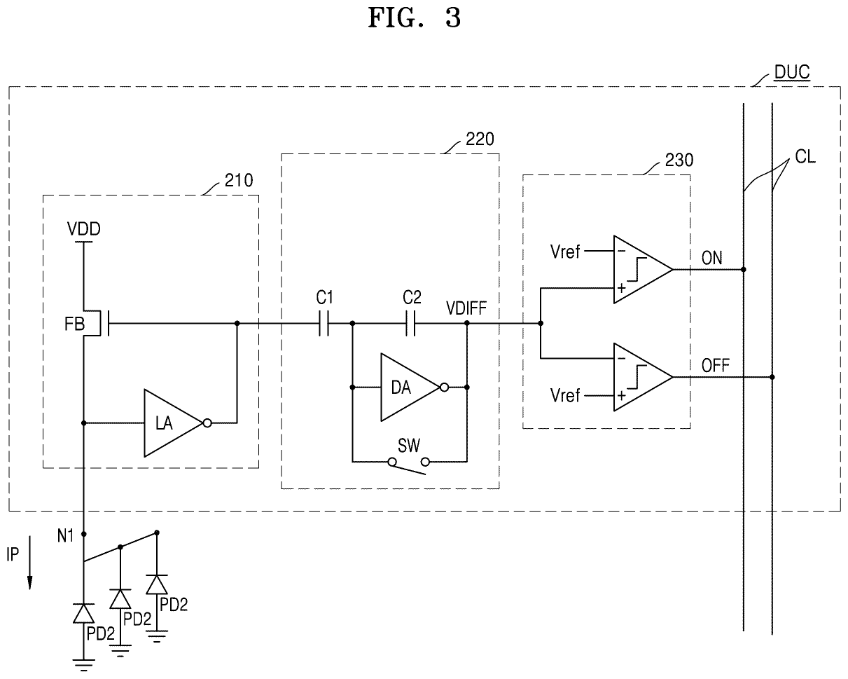

FIG. 3 is a circuit diagram illustrating three second-type photoelectric conversion elements PD2 and a DVS pixel unit circuit DUC according to an embodiment. For example, FIG. 3 is a circuit diagram illustrating the second pixel PX2.

The vision sensor 100 may include the DVS pixel unit circuit DUC. In an embodiment, the second pixel PX2 may include the plurality of second-type photoelectric conversion elements PD2 and the DVS pixel unit circuit DUC. The DVS pixel unit circuit DUC may include a current/voltage (I/V) converter 210, an amplifier circuit 220, and a comparator circuit 230, for detecting a change in the amount of light incident on the three second-type photoelectric conversion elements PD2. The DVS pixel unit circuit DUC may be connected to a first node N1. In an embodiment, the I/V converter 210, the amplifier circuit 220, and the comparator circuit 230 are disposed on a semiconductor die DIE2 in FIG. 3 or the I/V converter 210 is disposed on a semiconductor die DIE1 in FIG. 3 while the amplifier circuit 220 and the comparator circuit 230 are disposed on a semiconductor die DIE2.

For example, each of the three second-type photoelectric conversion elements PD2 may include a photodiode, a phototransistor, a pinned photodiode, or a similar device thereto. Each of the three second-type photoelectric conversion elements PD2 may be connected in parallel to the first node N1.

Each of the three second-type photoelectric conversion elements PD2 may be connected to the DVS pixel unit circuit DUC. Each of the three second-type photoelectric conversion elements PD2 may be connected to the first node N1 to share the I/V converter 210, the amplifier circuit 220, and the comparator circuit 230. In an embodiment, each of the three second-type photoelectric conversion elements PD2 may share the I/V converter 210 disposed on the semiconductor die DIE1 and be connected to the amplifier circuit 220 and the comparator circuit 230 disposed on the semiconductor DIE 2 through the first node N1.

The I/V converter 210 may include a logarithmic amplifier LA and a feedback transistor FB. The logarithmic amplifier LA may convert a photocurrent IP generated by at least one of the three second-type photoelectric conversion elements PD2s into a voltage and may amplify the voltage. The logarithmic amplifier LA may output a log voltage VLOG in a log scale. The logarithmic amplifier LA may be connected to the at least one of the second-type photoelectric conversion elements PD2. The feedback transistor FB may be connected to the at least one of the second-type photoelectric conversion elements PD2.

The amplifier circuit 220 may be configured to amplify the log voltage VLOG, which may be referred to as an input voltage, to generate an output voltage VDIFF. For example, the amplifier circuit 220 may include capacitors C1 and C2, a differential amplifier DA, and a switch SW operated by the reset signal RST. For example, the capacitors C1 and C2 may store electrical energy generated by at least one of the second-type photoelectric conversion elements PD2. For example, capacitance of the capacitors C1 and C2 may be appropriately selected considering the shortest time (for example, a refractory period) between two events that may occur continuously in one pixel. When the switch SW is switched on by the reset signal RST, a pixel may be initialized. The reset signal RST may be received from the row AER circuit of the event detection circuit 160.

The comparator circuit 230 may compare a level of the output voltage VDIFF to a reference voltage Vref of the differential amplifier DA, and determine whether the event detected by the pixel is an on-event or an off-event based on the result of the comparison. When an event of an increase in the intensity of light is detected, the comparator circuit 230 may output a signal ON indicating that the event is the on-event, and when an event of a decrease in the intensity of light is detected, the comparator circuit 230 may output the signal OFF indicating that the event is the off-event.

The configuration of the pixel illustrated in FIG. 3 is an example, and each of the M photoelectric conversion elements other than the three second-type photoelectric conversion elements PD2 may be connected to the first node N1, and may share the I/V converter 210, the amplifier circuit 220, and the comparator circuit 230, in case the I/V converter 210, the amplifier circuit 220, and the comparator circuit 230 are disposed on the semiconductor DIE 2, or may be connected to the first node N1 through the I/V converter 210 disposed on the semiconductor DIE 1 and may share the amplifier circuit 220 and the comparator circuit 230 in case the I/V converter 210 is disposed on the semiconductor DIE 1.

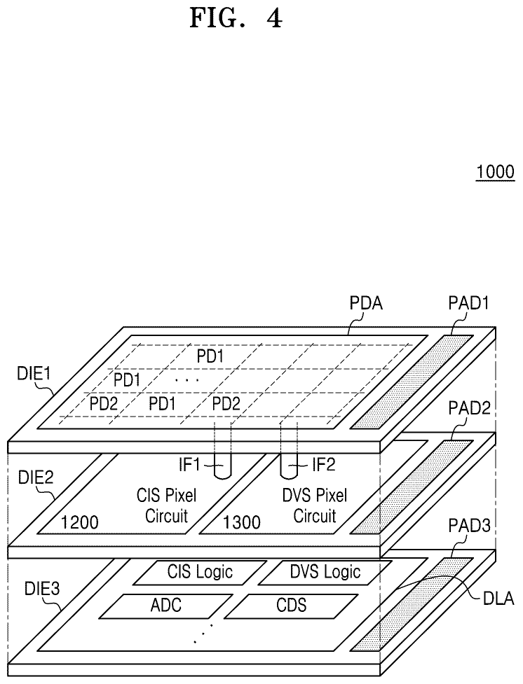

FIG. 4 illustrates a perspective view of a vision sensor 1000 including the first-type photoelectric conversion element PD1 and the second-type photoelectric conversion elements PD2 according to an embodiment. The vision sensor 1000 of FIG. 4 may correspond to the vision sensor 100 in FIG. 1.

An example embodiment of the vision sensor 1000 according to the embodiment of the inventive concept is described in terms of a physical structure. For example, an embodiment of the inventive concept is described based on semiconductor dies included in a vision sensor according to the embodiment of the inventive concept with reference to the drawings below. To explain the technical idea of the inventive concept, components illustrated in the drawings below are simplified, unlike actually-implemented semiconductor wafers, semiconductor chips, semiconductor dies, semiconductor packages, etc.

Referring to FIG. 4, the vision sensor 1000 may include first through third semiconductor dies DIE1 through DIE3. Each of the first through third semiconductor dies DIE1 through DIE3 may be manufactured from different semiconductor processes or may use different semiconductor wafers. The first semiconductor die DIE1 may be electrically connected to the second semiconductor die DIE2 and the semiconductor die DIE3 and may be on the second semiconductor die DIE2. The second semiconductor die DIE2 may be electrically connected to the third semiconductor die DIE3 and may be on the third semiconductor die DIE3. The second semiconductor die DIE2 may be located between the first and third semiconductor dies DIE1 and DIE3.

In the embodiment, the first semiconductor die DIE1 may include a photoelectric conversion element array area PDA and a first pad PAD1. The photoelectric conversion element array area PDA and the first pad PAD1 may be physically separated from each other or may be apart from each other by a certain distance. A plurality of first-type photoelectric conversion elements PD1 and a plurality of second-type photoelectric conversion elements PD2 may be arranged in the photoelectric conversion element array area PDA. The plurality of first-type photoelectric conversion elements PD1 and the plurality of second-type photoelectric conversion elements PD2 be formed in the photoelectric conversion element array area PDA of the first semiconductor die DIE1.

In the embodiment, the plurality of first-type photoelectric conversion elements PD may be connected to a CIS pixel circuit 1200 of the second semiconductor die DIE2 via a first connection structure IF1 and the plurality of second-type photoelectric conversion elements PD2 may be connected to a DVS pixel circuit 1300 via a second connection structure IF2. In an embodiment, charges generated by the plurality of first-type photoelectric conversion elements PD1 may be transmitted to the CIS pixel circuit 1200 via the first connection structure IF1, when both of a plurality of driving transistors and a plurality of selection transistors corresponding to the plurality of first photoelectric conversion elements PD1 are not disposed on the first semiconductor die DIE1. In addition, electrical signals generated based on the charges generated by the plurality of first-type photoelectric conversion elements PD1 may be transmitted to the CIS pixel circuit 1200 via the first connection structure IF1, when at least one of the plurality of driving transistors and the plurality of selection transistors is disposed on the second semiconductor die DIE2. Charges generated by the plurality of second-type photoelectric conversion elements PD2 or the amplified voltage generated based on charges generated by the plurality of second-type photoelectric conversion elements PD2 may be transmitted to the DVS pixel circuit 1300 via the second connection structure IF2.

In an embodiment, the first and second connection structures IF1 and IF2 may be various components for electrically connecting the plurality of first-type photoelectric conversion elements PD1 and second-type photoelectric conversion elements PDs to the CIS pixel circuit 1200 and the DVS pixel circuit 1300, respectively. For example, the first and second connection structures IF1 and IF2 may include an electrical wiring, a wire, a solder ball, a bump, or a through silicon via (TSV). For example, the first and second connection structures IF1 and IF2 may be connected to each other in a copper-to-copper (Cu-to-Cu) bonding manner. The first semiconductor die DIE1 and the second semiconductor die DIE2 may be connected to each other in a Cu-to-Cu bonding manner.

In an embodiment, the first connection structure IF1 may be arranged in an area where the photoelectric conversion element array area PDA, in which the plurality of first-type photoelectric conversion elements PD1 are arranged, overlaps the CIS pixel circuit 1200, and the second connection structure IF2 may be arranged in an area where the photoelectric conversion element array area PDA, in which the plurality of second-type photoelectric conversion elements PD2 are arranged, overlaps the DVS pixel circuit 1300.

In an embodiment, the second semiconductor die DIE2 may include the CIS pixel circuit 1200, the DVS pixel circuit 1300, and a second pad PAD2. The CIS pixel circuit 1200 may include a CIS photoelectric conversion element unit circuit connected to the plurality of first-type photoelectric conversion elements PD1. The CIS pixel circuit 1200 may include a plurality of CIS photoelectric conversion element unit circuits. The CIS photoelectric conversion element unit circuit may include a transmission transistor, a reset transistor, a driving transistor, a selection transistor, etc. In another embodiment, the CIS photoelectric conversion element unit circuit may include only a portion (for example, the driving transistor and the selection transistor) of the transmission transistor, the reset transistor, the driving transistor, and the selection transistor, and the remaining portions are disposed on the first semiconductor die DIE1. In another embodiment, the transmission transistor, the reset transistor, the driving transistor, and the selection transistor are disposed on the first semiconductor die DIE1 and output signals generated by the first semiconductor die DIE1 may be transmitted to the third semiconductor die DIE3 via connection structures connected to the first pad PAD1, the second pad PAD2, and/or a third pad PAD3. The DVS pixel circuit 1300 may include a plurality of DVS photoelectric conversion element unit circuits (DUCs of FIG. 3). In an embodiment, a portion (for example, the I/V converter 210) of the DVS photoelectric conversion element unit circuits DUCs is disposed on the first semiconductor DIE1 and the remaining portions are disposed on the second semiconductor DIE2.

In one embodiment, the second semiconductor die DIE2 may include only the DVS pixel circuit 1300. The first semiconductor die DIE1 may include the first pixel PX1 and second-type photoelectric conversion elements PD2. That is, the first semiconductor die DIE1 may have the first-type photoelectric conversion elements PD1, the transfer transistor, the reset transistor, the driving transistor, and the selection transistor, and the second-type photoelectric conversion elements PD2. The electrical signal output from the first pixel PX1 arranged in the first semiconductor die DIE1 may be transmitted to the third semiconductor die DIE3 via a connection structure.

In an embodiment, the plurality of first-type photoelectric conversion elements PD1 and a transmission transistor may be arranged on the first semiconductor die DIE1. A reset transistor, a driving transistor, a selection transistor, and the like, corresponding to the plurality of first-type photoelectric conversion elements PD1, may be arranged on the second semiconductor die DIE2.

In an embodiment, the CIS pixel circuit 1200 and the DVS pixel circuit 1300 of the second semiconductor die DIE2 may receive charges, voltage, or electrical signals from the first semiconductor die DIE1, and may generate an output signal (e.g., an electrical signal or an event signal). The output signal generated by the first semiconductor die DIE1 and/or the second semiconductor die DIE2 may be transmitted to the third semiconductor die DIE3 via connection structures connected to the first pad PAD1, the second pad PAD2, and/or a third pad PAD3.

In an embodiment, the third semiconductor die DIE3 may include a digital logic circuit area DLA and the third pad PAD3. The digital logic circuit area DLA may include an area for forming the RDV 120, the control logic circuit 130, and the signal processing circuit 140 in FIG. 2 described above.

The third semiconductor die DIE3 may include the remaining components not formed on the first semiconductor die DIE1 and the second semiconductor die DIE2, among the components of the vision sensor 100. For example, the third semiconductor die DIE3 may include CIS logic, DVS logic, an analog to digital converter (ADC), a correlated-double sampler (CDS), etc. For example, although not illustrated here, the third semiconductor die DIE3 may further include a processor (for example, the processor 11 in FIG. 1), an image signal processor, etc.

In an embodiment, in the first mode, as at least one of the transmission transistor, the driving transistor, and the selection transistor of the first pixel PX1 and the CIS logic may be deactivated, the first pixel PX1 does not output charges or electrical signals. In the second mode, the transmission transistor, the driving transistor, and the selection transistor of the first pixel PX1, and the CIS logic may be activated.

In an embodiment, the DVS pixel circuit 1300 and the DVS logic may be activated in the first mode. The DVS pixel circuit 1300 and the DVS logic may be activated in the second mode.

In an embodiment, the mode of the vision sensor 100 may be switched under the control by the control logic circuit 130 in FIG. 2. For example, the vision sensor 100 may switch from the first mode to the second mode or from the second mode to the first mode under the control by the control logic circuit 130.

In an embodiment, the mode of the vision sensor 100 may be switched under the control by the processor (for example, the processor 11 in FIG. 1) or the image signal processor ISP. For example, the vision sensor 100 may switch from the first mode to the second mode or from the second mode to the first mode under the control by the processor (for example, processor 11 in FIG. 1) or the image signal processor ISP. The vision sensor 100 may receive a mode conversion signal from the processor (for example, the processor 11 in FIG. 1) or the image signal processor ISP. The vision sensor 100 may switch a mode from the first mode to the second mode or from the second mode to the first mode in response to the mode conversion signal.

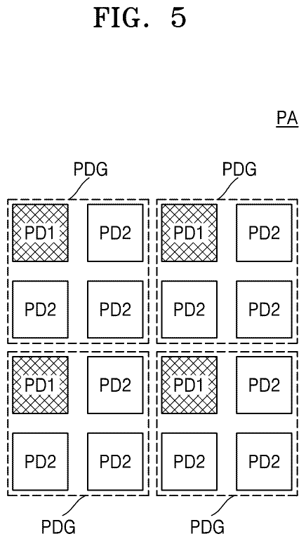

FIG. 5 is a diagram illustrating an example of a photoelectric conversion element array according to an embodiment of the present disclosure.

Referring to FIGS. 2 and 5, the pixel array 110 may include the photoelectric conversion element array PA. The photoelectric conversion element array PA may include a plurality of photoelectric conversion element groups PDG arranged in rows and columns. The photoelectric conversion element group PDG may include a plurality of second-type photoelectric conversion elements PD2 and at least one first-type photoelectric conversion element PD1. In the photoelectric conversion element group PDG, the number of first-type photoelectric conversion elements PD1 may be less than the number of second-type photoelectric conversion elements PD2.

In an embodiment, the photoelectric conversion element group PDG may include M second-type photoelectric conversion elements PD2 and N first-type photoelectric conversion elements PD1. For example, M may be ‘3’, and N may be ‘1’. In the photoelectric conversion element group PDG, a first row and a first column may correspond to the first-type photoelectric conversion element PD1, the first row and a second column may correspond to the second-type photoelectric conversion element PD2, a second row and the first column may correspond to the second-type photoelectric conversion element PD2, and the second row and the second column may correspond to the second-type photoelectric conversion element PD2.

The photoelectric conversion element array PA may include 16 photoelectric conversion elements arranged in a 4×4 array (for example, 4 rows by 4 columns). The photoelectric conversion element array PA may include four photoelectric conversion element groups PDG arranged in a 2×2 array (for example, 2 rows by 2 columns). The position of the first-type photoelectric conversion element PD1 in the photoelectric conversion element groups PDG may be the same in each photoelectric conversion element group PDG. That is, in each photoelectric conversion element group PGD, relative positions of the first-type photoelectric conversion elements PD1 with respect to the photoelectric conversion element groups PGD are identical. For example, the first-type photoelectric conversion element PD1 may be arranged on the first row and the first column in the photoelectric conversion element group PDG. In the photoelectric conversion element array PA, the first-type photoelectric conversion element PD1 may be arranged on the first row and the first column, the first-type photoelectric conversion element PD1 may be arranged on the first row and the third column, the first-type photoelectric conversion element PD1 may be arranged on the third row and the first column, and the first-type photoelectric conversion element PD1 may be arranged on the third row and the third column.

The plurality of first-type photoelectric conversion elements PD1 included in the photoelectric conversion element group PDG may share the CIS photoelectric conversion element unit circuits and the plurality of second-type photoelectric conversion elements PD2 included in the photoelectric conversion element group PDG may share the DVS pixel unit circuit DUC.

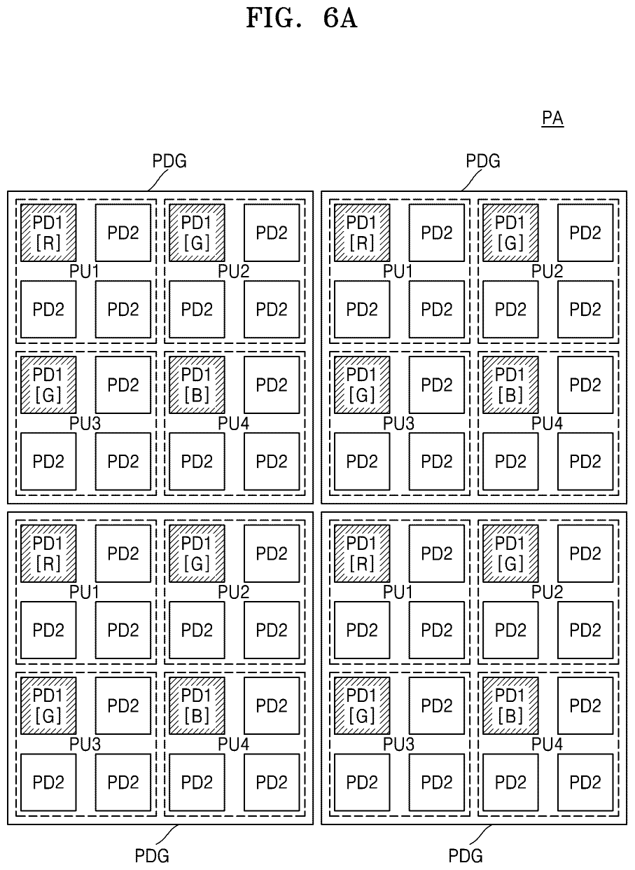

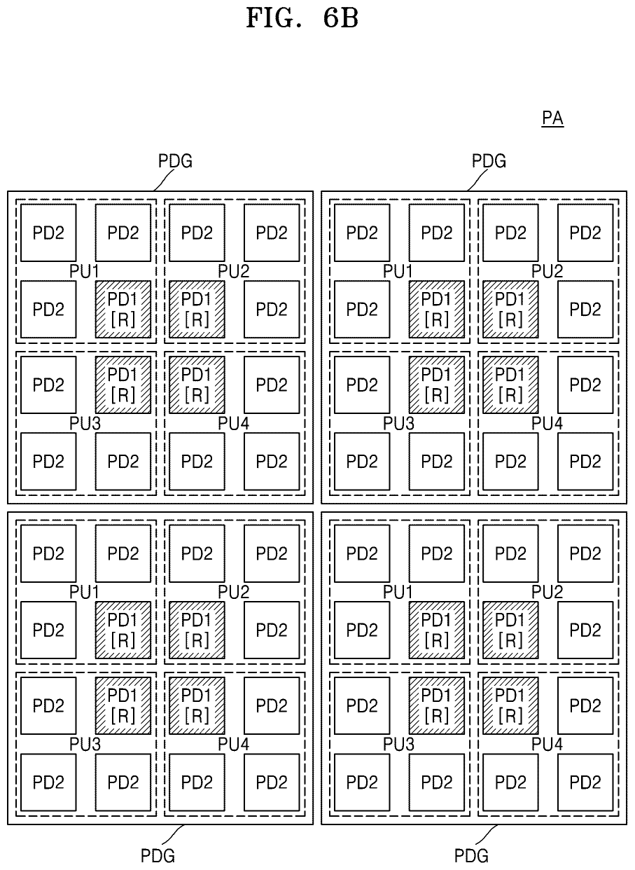

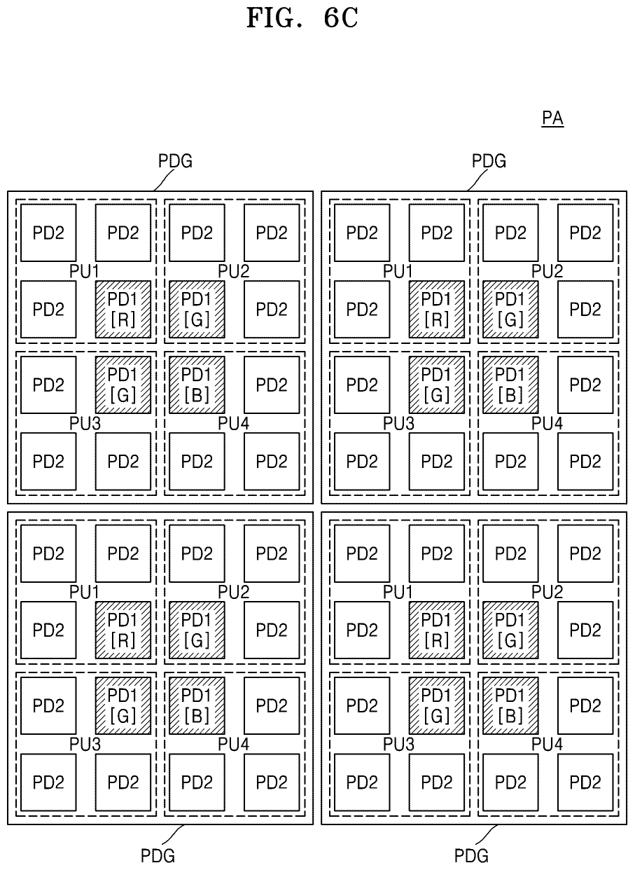

FIGS. 6A through 6C are diagrams illustrating an example of a photoelectric conversion element array according to an embodiment of the present disclosure.

Referring to FIGS. 6A, 6B, and 6C, the pixel array 110 may include ‘64’ photoelectric conversion elements arranged in an 8×8 array (for example, 8 rows by 8 columns). The photoelectric conversion element array PA may include four photoelectric conversion element groups PDG arranged in a 2×2 array (for example, 2 rows by 2 columns). The photoelectric conversion element group PDG may include four photoelectric conversion element units, for example, first through fourth photoelectric conversion element units PU1 through PU4 arranged in a 2×2 array (for example, 2 rows by 2 columns). Each of the first through fourth photoelectric conversion element units PU1 through PU4 may include ‘4’ photoelectric conversion elements arranged in a 2×2 array (for example, 2 rows by 2 columns).

In an embodiment, each of the first through fourth photoelectric conversion element units PU1 through PU4 may include M second-type photoelectric conversion elements PD2 and N first-type photoelectric conversion elements PD1. In this case, M and N may include natural numbers, and M may be greater than N. For example, M may be 3, and N may be 1. In each of the first through fourth photoelectric conversion element units PU1 through PU4, the total number of second-type photoelectric conversion elements PD2 may be greater than the total number of first-type photoelectric conversion elements PD1.

In an embodiment, the positions of the first-type photoelectric conversion elements PD1 included in each of the first through fourth photoelectric conversion element units PU1 through PU4 included in the photoelectric conversion element group PDG may all be the same. Referring to FIG. 6A, in each of the first through fourth photoelectric conversion element units PU1 through PU4, the first-type photoelectric conversion element PD1 may be arranged on the first row and the first column, the second-type photoelectric conversion element PD2 may be arranged on the first row and the second column, the second-type photoelectric conversion element PD2 may be arranged on the second row and the first column, and the second-type photoelectric conversion element PD2 may be arranged on the second row and the second column.

In an embodiment, the first-type photoelectric conversion elements PD1 included in the photoelectric conversion element group PDG may be the same as or different from each other. The first-type photoelectric conversion elements PD1 included in the first through fourth photoelectric conversion element units PU1 through PU4 may be of the same type or different types. For example, the first pixels PX1 corresponding to the first-type photoelectric conversion elements PD1 may have a pixel structure of any one of RGGB, RCCC, RYYC, RGBC, RGBW, etc. However, the scope of the inventive is not limited thereto, and the first pixels PX1 corresponding to the first-type photoelectric conversion elements PD1 may include the red R pixel, the green G pixel, the blue B pixel, a cyan C pixel, a yellow Y pixel, a magenta M pixel, a clear CL pixel, a white W pixel, or a combination thereof.

The pixel group PG may have four first pixels PX1. The photoelectric conversion element group PDG may have four first-type photoelectric conversion elements PD1. The photoelectric conversion element group PDG may include the first-type photoelectric conversion element PD1 corresponding to one red R pixel, the first-type photoelectric conversion elements PD1 corresponding to two green G pixels, and the first-type photoelectric conversion element PD1 corresponding to one blue B pixel. The first pixels PX1 of the pixel group PG may have an RGGB pixel structure. For example, the first-type photoelectric conversion element PD1 of a first photoelectric conversion element unit PU1 may correspond to the red R pixel, the first-type photoelectric conversion element PD1 of a second photoelectric conversion element unit PU2 may correspond to the green G pixel, the first-type photoelectric conversion element PD1 of a third photoelectric conversion element unit PU3 may correspond to the green G pixel, and the first-type photoelectric conversion element PD1 of a fourth photoelectric conversion element unit PU4 may correspond to the blue B pixel.

For example, the first pixels PX1 of the pixel group PG may have an RCCC pixel structure. For example, the pixel group PG may include one red R pixel and three cyan C pixels. For example, the first-type photoelectric conversion element PD1 of the first photoelectric conversion element unit PU1 may correspond to the red R pixel, the first-type photoelectric conversion element PD1 of the second photoelectric conversion element unit PU2 may correspond to the cyan C pixel, the first-type photoelectric conversion element PD1 of the third photoelectric conversion element unit PU3 may correspond to the cyan C pixel, and the first-type photoelectric conversion element PD1 of the fourth photoelectric conversion element unit PU4 may correspond to the cyan C pixel.

The first pixels PX1 of the pixel group PG may have an RYYC pixel structure. For example, the pixel group PG may include one red R pixel, two yellow Y pixels, and one cyan C pixel. For example, the first-type photoelectric conversion element PD1 of the first photoelectric conversion element unit PU1 may correspond to the red R pixel, the first-type photoelectric conversion element PD1 of the second photoelectric conversion element unit PU2 may correspond to the yellow Y pixel, the first-type photoelectric conversion element PD1 of the third photoelectric conversion element unit PU3 may correspond to the yellow Y pixel, and the first-type photoelectric conversion element PD1 of the fourth photoelectric conversion element unit PU4 may correspond to the cyan C pixel.

The first pixels PX1 of the pixel group PG may have an RGBC pixel structure. For example, the pixel group PG may include one red R pixel, one green G pixel, one blue B pixel, and one cyan C pixel. For example, the first-type photoelectric conversion element PD1 of the first photoelectric conversion element unit PU1 may correspond to the red R pixel, the first-type photoelectric conversion element PD1 of the second photoelectric conversion element unit PU2 may correspond to the green G pixel, the first-type photoelectric conversion element PD1 of the third photoelectric conversion element unit PU3 may correspond to the blue B pixel, and the first-type photoelectric conversion element PD1 of the fourth photoelectric conversion element unit PU4 may correspond to the cyan C pixel.

The first pixels PX1 of the pixel group PG may have an RGBW pixel structure. For example, the pixel group PG may include one red R pixel, one green G pixel, one blue B pixel, and one cyan C pixel. For example, the first-type photoelectric conversion element PD1 of the first photoelectric conversion element unit PU1 may correspond to the red R pixel, the first-type photoelectric conversion element PD1 of the second photoelectric conversion element unit PU2 may correspond to the green G pixel, the first-type photoelectric conversion element PD1 of the third photoelectric conversion element unit PU3 may correspond to the blue B pixel, and the first-type photoelectric conversion element PD1 of the fourth photoelectric conversion element unit PU4 may correspond to the white W pixel.

In an embodiment, the first pixels PX1 included in the pixel group PG may not share the reset transistor, the driving transistor, and the selection transistor. The first pixel PX1, corresponding to the first-type photoelectric conversion element PD1 of each of the first through fourth photoelectric conversion element units PU1 through PU4, may include a unique reset transistor, a unique driving transistor, and a unique selection transistor (e.g., each first pixel PX1 may have a corresponding reset transistor, a driving transistor, and a selection transistor).

For example, the first pixel PX1 corresponding to the first photoelectric conversion element unit PU1 may include the first-type photoelectric conversion element PD1, a first transmission transistor, a first reset transistor, a first driving transistor, and a first selection transistor, the first pixel PX1 corresponding to the second photoelectric conversion element unit PU2 may include the first-type photoelectric conversion element PD1, a second transmission transistor, a second driving transistor, and a second selection transistor, the first pixel PX1 corresponding to the third photoelectric conversion element unit PU3 may include the first-type photoelectric conversion element PD1, a third transmission transistor, a third reset transistor, a third driving transistor, and a third selection transistor, and the first pixel PX1 of the fourth photoelectric conversion element unit PU4 may include the first-type photoelectric conversion element PD1, a fourth transmission transistor, a fourth reset transistor, a fourth driving transistor, and a fourth selection transistor. The first through fourth reset transistors may be different from each other, the first through fourth driving transistors may be different from each other, and the first through fourth selection transistors may be different from each other.

The first-type photoelectric conversion element PD1, the transmission transistor, the reset transistor, the driving transistor, and the selection transistor included in the first pixel PX1 may be formed on the first semiconductor die DIE1. Alternatively or additionally, the dual conversion transistor further included in the first pixel PX1 may be formed on the first semiconductor die DIE1. The plurality of second-type photoelectric conversion elements PD2 may be formed on the first semiconductor die DIE1. The plurality of second-type photoelectric conversion elements PD2 included in the photoelectric conversion element group PDG may share the DVS pixel unit circuit DUC. The DVS pixel unit circuit DUC may be formed on the second semiconductor die DIE2.

Referring to FIG. 6B, the positions of the first-type photoelectric conversion elements PD1 included in each of the first through fourth photoelectric conversion element units PU1 through PU4 included in the photoelectric conversion element group PDG may all be different from each other. For example, in the first photoelectric conversion element unit PU1, the second-type photoelectric conversion element PD2 may be arranged on the first row and the first column, the second-type photoelectric conversion element PD2 may be arranged on the first row and the second column, the second-type photoelectric conversion element PD2 may be arranged on the second row and the first column, and the first-type photoelectric conversion element PD1 may be arranged on the second row and the second column. In the second photoelectric conversion element unit PU2, the second-type photoelectric conversion element PD2 may be arranged on the first row and the first column, the second-type photoelectric conversion element PD2 may be arranged on the first row and the second column, the first-type photoelectric conversion element PD1 may be arranged on the second row and the first column, and the second-type photoelectric conversion element PD2 may be arranged on the second row and the second column. In the third photoelectric conversion element unit PU3, the second-type photoelectric conversion element PD2 may be arranged on the first row and the first column, the first-type photoelectric conversion element PD1 may be arranged on the first row and the second column, the second-type photoelectric conversion element PD2 may be arranged on the second row and the first column, and the second-type photoelectric conversion element PD2 may be arranged on the second row and the second column. In the fourth photoelectric conversion element unit PU4, the first-type photoelectric conversion element PD1 may be arranged on the first row and the first column, the second-type photoelectric conversion element PD2 may be arranged on the first row and the second column, the second-type photoelectric conversion element PD2 may be arranged on the second row and the first column, and the second-type photoelectric conversion element PD2 may be arranged on the second row and the second column.

For example, in the photoelectric conversion element group PDG, the first-type photoelectric conversion element PD1 may be arranged on the second row and the second column, the first-type photoelectric conversion element PD1 may be arranged on the first row and the third column, the first-type photoelectric conversion element PD1 may be arranged on the third row and the second column, and the first-type photoelectric conversion element PD1 may be arranged on the third row and the third column. Each of the first-type photoelectric conversion elements PD1 may be arranged at an edge portion of a photoelectric conversion element unit where one of the first through fourth photoelectric conversion element units PU1 through PU4 meets another of the first through fourth photoelectric conversion element units PU1 through PU4 (e.g., the first photoelectric conversion element units of a group may each be located within a respective photoelectric conversion element unit such that the first-type photoelectric conversion elements PD1 of an adjacent photoelectric conversion element unit are adjacent to one another). Each of the first-type photoelectric conversion elements PD1 may be arranged at the center portion of the photoelectric conversion element group PDG.

In an embodiment, the first pixels PX1 included in the pixel group PG may be the same as each other. The first pixels PX1, corresponding to first-type photoelectric conversion elements PD1 included in the first through fourth photoelectric conversion element units PU1 through PU4, may be of the same type. For example, each of the first pixels PX1 included in the pixel group PG may include the red R pixel. For example, the first-type photoelectric conversion element PD1 included in the first photoelectric conversion element unit PU1 may correspond to the red R pixel, the first-type photoelectric conversion element PD1 included in the second photoelectric conversion element unit PU2 may correspond to the red R pixel, the first-type photoelectric conversion element PD1 included in the third photoelectric conversion element unit PU3 may correspond to the red R pixel, and the first-type photoelectric conversion element PD1 included in the fourth photoelectric conversion element unit PU4 may correspond to the red R pixel.

In an embodiment, the first pixels PX1 included in the pixel group PG may not share the reset transistor, the driving transistor, and the selection transistor. The first pixels PX1, corresponding to the first-type photoelectric conversion elements PD1 of each of the first through fourth photoelectric conversion element units PU1 through PU4, may individually include the reset transistors, the driving transistors, and the selection transistors, which are different from each other.

In an embodiment, the plurality of first-type photoelectric conversion elements PD1 included in the photoelectric conversion element group PDG may share the reset transistor, the driving transistor, and the selection transistor. In addition, the plurality of first-type photoelectric conversion elements PD1 of the photoelectric conversion element group PDG may share a floating diffusion area. In an embodiment, the plurality of first-type photoelectric conversion elements PD1 of the photoelectric conversion element group PDG may further share the dual conversion transistor.

In an embodiment, the plurality of second-type photoelectric conversion elements PD2 of the photoelectric conversion element unit PU (each of the first through fourth photoelectric conversion element units PU1 through PU4) may share the DVS pixel unit circuit DUC. The plurality of second-type photoelectric conversion elements PD2 of the photoelectric conversion element unit PU may share the I/V converter 210, the amplifier circuit 220, and the comparator circuit 230. The plurality of second-type photoelectric conversion elements PD2 of the first photoelectric conversion element unit PU1 of the photoelectric conversion element group PDG may share a first DVS pixel unit circuit, the plurality of second-type photoelectric conversion elements PD2 of the second photoelectric conversion element unit PU2 of the photoelectric conversion element group PDG may share a second DVS pixel unit circuit, the plurality of second-type photoelectric conversion elements PD2 of the third photoelectric conversion element unit PU3 of the photoelectric conversion element group PDG may share a third DVS pixel unit circuit, and the plurality of second-type photoelectric conversion elements PD2 of the fourth photoelectric conversion element unit PU4 of the photoelectric conversion element group PDG may share a fourth DVS pixel unit circuit. The first through fourth DVS pixel unit circuits may be different from each other. Each of the first through fourth DVS pixel unit circuits may include a I/V converter, an amplifier circuit, and a comparator circuit. Each of the first through fourth DVS pixel unit circuits may be the same as or similar to the DVS pixel unit circuit DUC of FIG. 3.

In an embodiment, the plurality of second-type photoelectric conversion elements PD2 of the photoelectric conversion element group PDG may share the shared DVS pixel unit circuit DUC. All of the plurality of second-type photoelectric conversion elements PD2 of the photoelectric conversion element group PDG may share the I/V converter 210, the amplifier circuit 220, and the comparator circuit 230. For example, in the photoelectric conversion element group PDG, the plurality of second-type photoelectric conversion elements PD2 included in the first photoelectric conversion element unit PU1, the second-type photoelectric conversion elements PD2 included in the second photoelectric conversion element unit PU2, the second-type photoelectric conversion elements PD2 included in the third photoelectric conversion element unit PU3, and the plurality of second-type photoelectric conversion elements PD2 included in the fourth photoelectric conversion element unit PU4 may all share the same DVS pixel unit circuit DUC. Referring to FIG. 6C, the first pixels PX1 included in the pixel group PG may be the same as or different from each other. The first pixels PX1 included in the pixel units PU may be of the same type or different types. The pixel group PG may have four first pixels PX1. The photoelectric conversion element group PDG may include the first-type photoelectric conversion element PD1 corresponding to one red R pixel, the first-type photoelectric conversion elements PD1 corresponding to two green G pixels, and the first-type photoelectric conversion element PD1 corresponding to one blue B pixel. The first pixels PX1 of the pixel group PG may have an RGGB pixel structure. For example, the first-type photoelectric conversion element PD1 of the first photoelectric conversion element unit PU1 may correspond to the red R pixel, the first-type photoelectric conversion element PD1 of the second photoelectric conversion element unit PU2 may correspond to the green G pixel, the first-type photoelectric conversion element PD1 of the third photoelectric conversion element unit PU3 may correspond to the green G pixel, and the first-type photoelectric conversion element PD1 of the fourth photoelectric conversion element unit PU4 may correspond to the blue B pixel.

For example, the first pixels PX1 included in the pixel group PG may have a pixel structure of any one of RGGB, RCCC, RYYC, RGBC, RGBW, etc. However, the scope of the inventive is not limited thereto, and the first pixels PX1 of the pixel group PG may include the red R pixel, the green G pixel, the blue B pixel, a cyan C pixel, a yellow Y pixel, a magenta M pixel, a clear CL pixel, a white W pixel, or a combination thereof.

In an embodiment, the plurality of first-type photoelectric conversion elements PD1 included in the photoelectric conversion element group PDG may share the reset transistor, the driving transistor, and the selection transistor. In addition, the plurality of first-type photoelectric conversion elements PD1 of the photoelectric conversion element group PDG may share the floating diffusion area. In an embodiment, the plurality of first-type photoelectric conversion elements PD1 of the photoelectric conversion element group PDG may further share the dual conversion transistor.

In an embodiment, each of the plurality of photoelectric conversion element groups PDG may comprise a plurality of photoelectric conversion elements arranged in N rows and M columns. The plurality of photoelectric conversion elements may include the first-type photoelectric conversion element PD1 and the second-type photoelectric conversion element PD2. For example, the first-type photoelectric conversion element PD1 in each of the plurality of photoelectric conversion element groups may be disposed at the center portion of an array of N rows and M columns. In this case, N and M are integers. For example, the first-type photoelectric conversion element may be disposed at one of the four corners formed by an array of N rows and M columns. In this case, N and M are integers. For example, the first-type photoelectric conversion elements in a first photoelectric conversion element group may be directly adjacent to the first-type photoelectric conversion elements in a second photoelectric conversion element group. The first photoelectric conversion element group may be directly adjacent to the second photoelectric conversion element group.

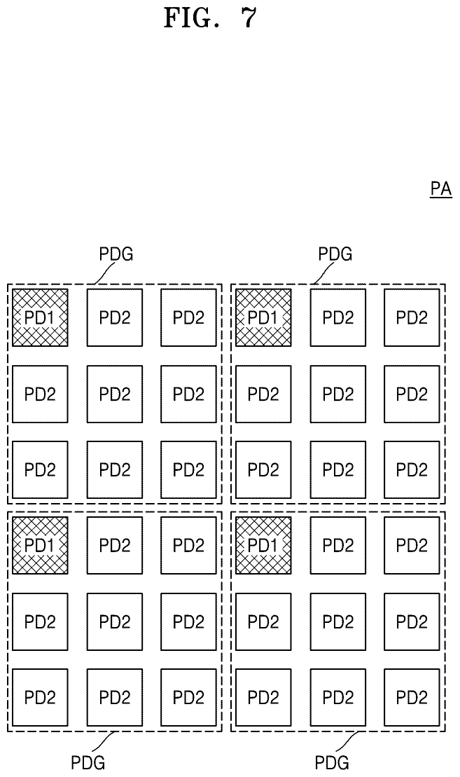

FIG. 7 is a diagram illustrating an example of a photoelectric conversion element array according to an embodiment of the present disclosure.

Referring to FIG. 5, the photoelectric conversion element array PA may include the plurality of photoelectric conversion element groups PDG arranged in rows and columns. The photoelectric conversion element group PDG may include the plurality of second-type photoelectric conversion elements PD2 and at least one first-type photoelectric conversion element PD1. In the photoelectric conversion element group PDG, the number of first-type photoelectric conversion elements PD1 may be less than the number of second-type photoelectric conversion elements PD2.

In an embodiment, the photoelectric conversion element group PDG may include M second-type photoelectric conversion elements PD2 and N first-type photoelectric conversion elements PD1. For example, M may be ‘8’, and N may be ‘1’. In the photoelectric conversion element group PDG, the first row and the first column may correspond to the first-type photoelectric conversion element PD1, the first row and the second column may correspond to the second-type photoelectric conversion element PD2, the first row and the third column may correspond to the second-type photoelectric conversion element PD2, the second row and the first column may correspond to the second-type photoelectric conversion element PD2, the second row and the second column may correspond to the second-type photoelectric conversion element PD2, the second row and the third column may correspond to the second-type photoelectric conversion element PD2, the third row and the first column may correspond to the second-type photoelectric conversion element PD2, the third row and the second column may correspond to the second-type photoelectric conversion element PD2, and the third row and the third column may correspond to the second-type photoelectric conversion element PD2.

For example, the photoelectric conversion element array PA may include 36 photoelectric conversion elements arranged in a 6×6 array (for example, 6 rows by 6 columns). The photoelectric conversion element array PA may include four photoelectric conversion element groups PDG arranged in a 2×2 array (for example, 2 rows by 2 columns). The position of the first-type photoelectric conversion element PD1 in the photoelectric conversion element groups PDG may be the same. For example, the first-type photoelectric conversion element PD1 may be arranged on the first row and the first column in the photoelectric conversion element group PDG. In the photoelectric conversion element array PA, the first-type photoelectric conversion element PD1 may be arranged on the first row and the first column, the first-type photoelectric conversion element PD1 may be arranged on the first row and a fourth column, the first-type photoelectric conversion element PD1 may be arranged on a fourth row and the first column, and the first-type photoelectric conversion element PD1 may be arranged on the fourth row and the fourth column.

In an embodiment, the first pixel PX1 corresponding to the first-type photoelectric conversion element PD1 may be any one of the red R pixel, the green G pixel, the blue B pixel, the cyan C pixel, the yellow Y pixel, the magenta M pixel, the clear CL pixel, etc.

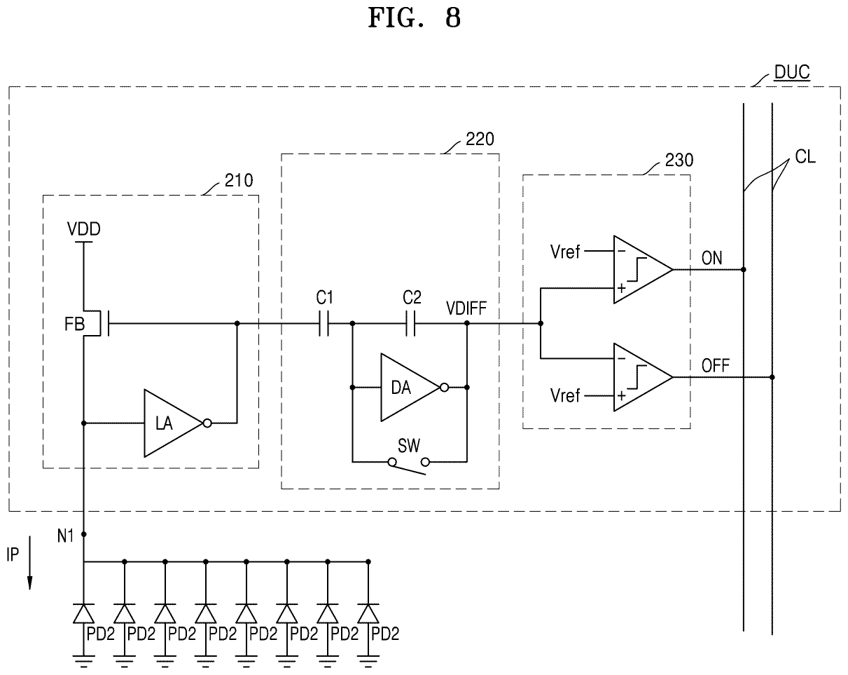

FIG. 8 is a circuit diagram illustrating eight second-type photoelectric conversion elements PD2 of the photoelectric conversion element group PDG in FIG. 7, and a DVS pixel unit circuit DUC according to an embodiment.

Referring to FIGS. 3, 7, and 8, the DVS pixel unit circuit DUC may include the I/V converter 210, the amplifier circuit 220, and the comparator circuit 230 for detecting a change in the amount of light incident on the eight second-type photoelectric conversion elements PD2. The DVS pixel unit circuit DUC may be connected to the first node N1. For convenience of descriptions, duplicate descriptions of components given above may be omitted.

Each of the eight second-type photoelectric conversion elements PD2 may be connected to the first node N1. Each of the eight second-type photoelectric conversion elements PD2 may be connected to the DVS pixel unit circuit DUC. Each of the eight second-type photoelectric conversion elements PD2 may be connected to the first node N1, and share the I/V converter 210, the amplifier circuit 220, and the comparator circuit 230. For example, all of the plurality of second-type photoelectric conversion elements PD2 included in the photoelectric conversion element group PDG may share the DVS pixel unit circuit DUC.

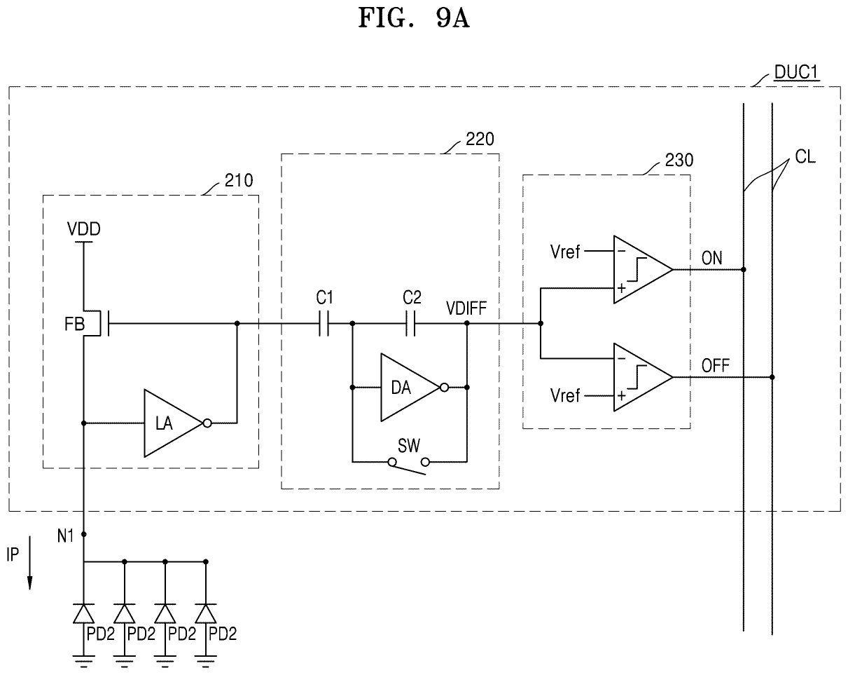

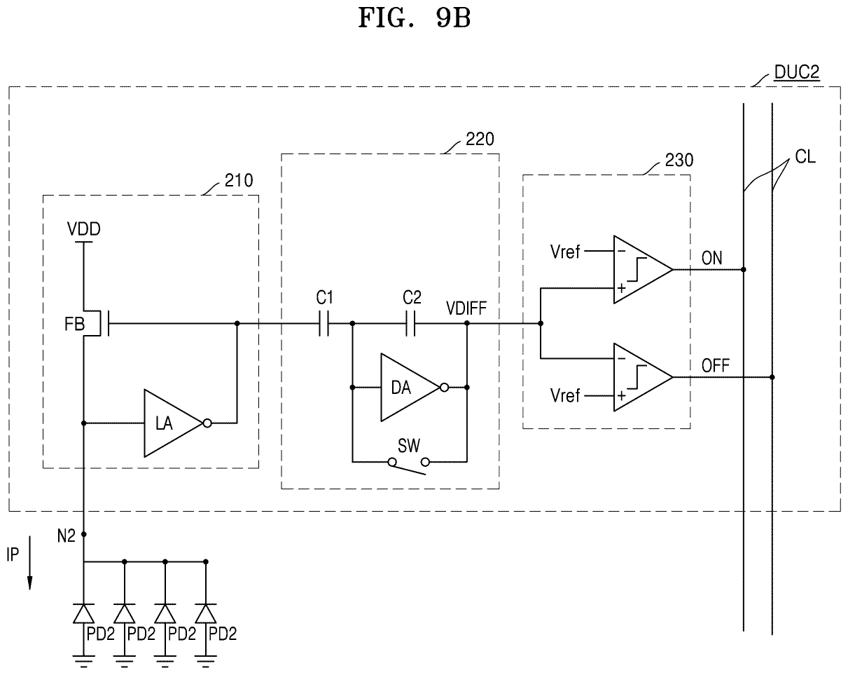

FIG. 9A is a circuit diagram illustrating four second-type photoelectric conversion elements PD2 of the photoelectric conversion element group PDG in FIG. 7, and a first DVS pixel unit circuit DUC1 according to an embodiment. FIG. 9B is a circuit diagram illustrating the remaining four second-type photoelectric conversion elements PD2 of the photoelectric conversion element group PDG in FIG. 7, and a second DVS pixel unit circuit DUC2 according to an embodiment.

In an embodiment, a first portion of the plurality of second-type photoelectric conversion elements PD2 included in the photoelectric conversion element group PDG may share the first DVS pixel unit circuit DUC1, and a second portion of the plurality of second-type photoelectric conversion elements PD2 included in the photoelectric conversion element group PDG may share the second DVS pixel unit circuit DUC2.

Referring to FIGS. 3, 7, and 9A, the first DVS pixel unit circuit DUC1 may include the I/V converter 210, the amplifier circuit 220, and the comparator circuit 230 for detecting a change in the amount of light incident on the first portion of the plurality of second-type photoelectric conversion elements PD2. The first DVS pixel unit circuit DUC1 may be connected to the first node N1. For convenience of descriptions, duplicate descriptions of components given above may be omitted.

The first portion of the plurality of second-type photoelectric conversion elements PD2 may be connected to the first node N1. The first portion of the plurality of second-type photoelectric conversion elements PD2 may be connected to the first DVS pixel unit circuit DUC1. The first portion of the plurality of second-type photoelectric conversion elements PD2 may be connected to the first node N1, and share the I/V converter 210, the amplifier circuit 220, and the comparator circuit 230 of the first DVS pixel unit circuit DUC1.

Referring to FIGS. 3, 7, and 9B, the second DVS pixel unit circuit DUC2 may include the I/V converter 210, the amplifier circuit 220, and the comparator circuit 230 for detecting a change in the amount of light incident on the second portion of the plurality of second-type photoelectric conversion elements PD2. The second DVS pixel unit circuit DUC2 may be connected to a second node N2. The second node N2 may be different from the first node N1. For convenience of descriptions, duplicate descriptions of components given above may be omitted.

The second portion of the plurality of second-type photoelectric conversion elements PD2 may be connected to the second node N2. The second portion of the plurality of second-type photoelectric conversion elements PD2 may be connected to the second DVS pixel unit circuit DUC2. The second portion of the plurality of second-type photoelectric conversion elements PD2 may be connected to the second node N2, and share the I/V converter 210, the amplifier circuit 220, and the comparator circuit 230 of the second DVS pixel unit circuit DUC2.

In an embodiment, the number of second-type photoelectric conversion elements PD2 in the photoelectric conversion element group PDG is at least K times greater than the number of first-type photoelectric conversion elements PD1. In this case, K may be integer. For example, in the photoelectric conversion element group PDG, the total number of second-type photoelectric conversion elements PD2 is more than twice the total number of first-type photoelectric conversion elements PD1. In the photoelectric conversion element group PDG, the total number of second-type photoelectric conversion elements PD2 is more than three times the total number of first-type photoelectric conversion elements PD1. In the photoelectric conversion element group PDG, the total number of second-type photoelectric conversion elements PD2 is more than four times the total number of first-type photoelectric conversion elements PD1.

In an embodiment, when the number of second-type photoelectric conversion elements PD2 in the photoelectric conversion element group PDG is K times or more greater than the number of first-type photoelectric conversion elements PD1, the first portion of plurality of second-type photoelectric conversion elements PD2 included in the photoelectric conversion element group PDG may share the first DVS pixel unit circuit DUC1, and the second portion of the plurality of second-type photoelectric conversion elements PD2 included in the photoelectric conversion element group PDG may share the second DVS pixel unit circuit DUC2. In this case, K may be a natural number greater than ‘2’.

The first portion of the plurality of second-type photoelectric conversion elements PD2 included in the photoelectric conversion element group PDG may be referred to as a first set, and the second portion of the plurality of second-type photoelectric conversion elements PD2 included in the photoelectric conversion element group PDG may be referred to as a second set. For example, the number of second-type photoelectric conversion elements PD2 included in the photoelectric conversion element group PDG may be ‘8’, the number of second-type photoelectric conversion elements PD2 included in the first set may be ‘4’, and the number of second-type photoelectric conversion elements PD2 included in the second set may be ‘4’.

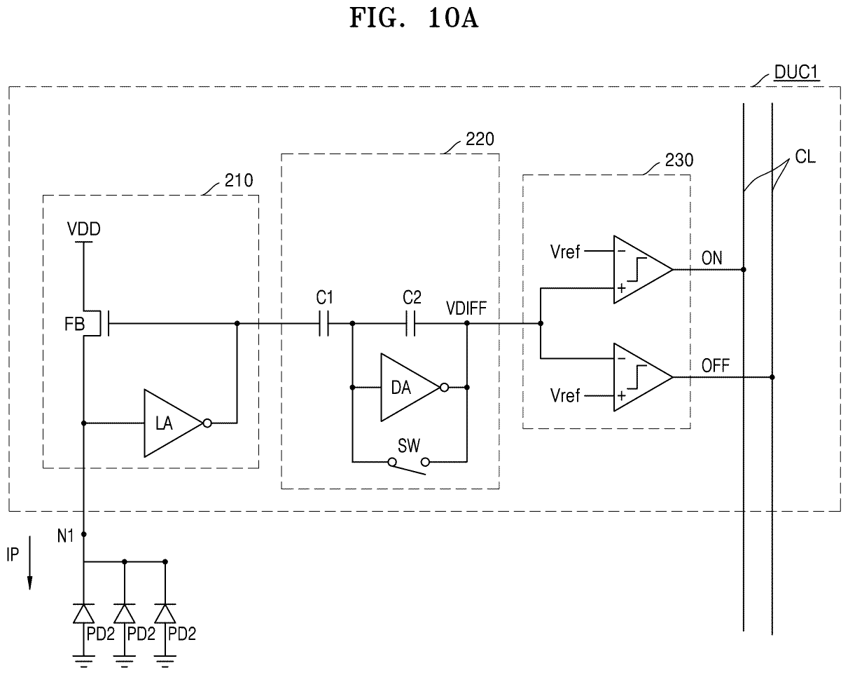

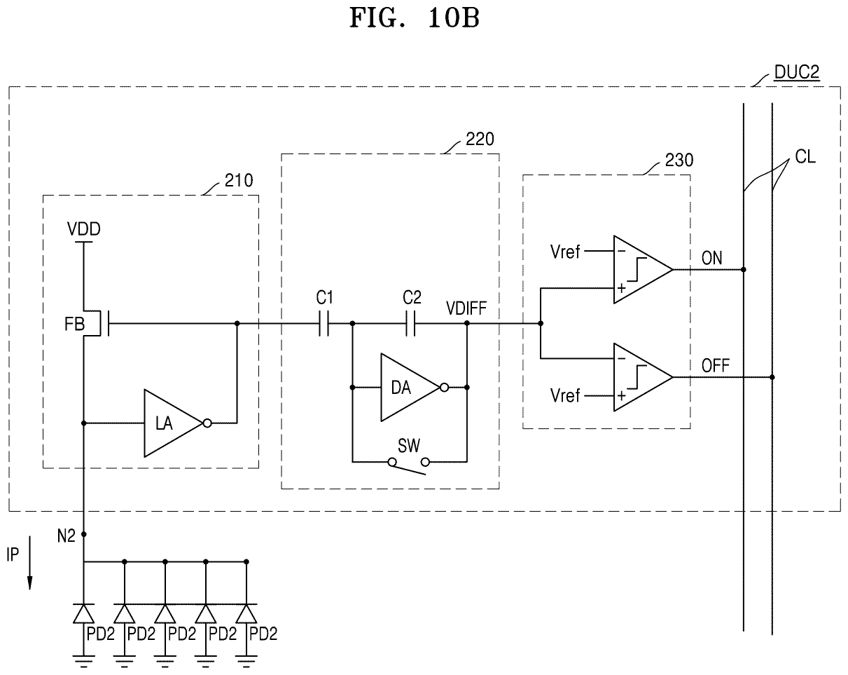

FIG. 10A is a circuit diagram illustrating three second-type photoelectric conversion elements PD2 of the photoelectric conversion element group PDG in FIG. 7, and a first DVS pixel unit circuit DUC1 according to an embodiment. FIG. 10B is a circuit diagram illustrating the remaining five second-type photoelectric conversion elements PD2 of the photoelectric conversion element group PDG in FIG. 7, and a second DVS pixel unit circuit DUC2 according to an embodiment. For convenience of descriptions, duplicate descriptions of components given above may be omitted.

The first portion of the second-type photoelectric conversion elements PD2 included in the photoelectric conversion element group PDG may be referred to as the first set, and the second portion of the second-type photoelectric conversion elements PD2 included in the photoelectric conversion element group PDG may be referred to as the second set. In an embodiment, the number of second-type photoelectric conversion elements PD2 included in the first set may be different from the number of second-type photoelectric conversion elements PD2 included in the second set.

Referring to FIG. 10A, the first portion of the second-type photoelectric conversion elements PD2 may be connected to the first node N1, and share the I/V converter 210, the amplifier circuit 220, and the comparator circuit 230 of the first DVS pixel unit circuit DUC1.

Referring to FIG. 10B, the second portion of the second-type photoelectric conversion elements PD2 may be connected to the second node N2, and share the I/V converter 210, the amplifier circuit 220, and the comparator circuit 230 of the second DVS pixel unit circuit DUC2.

In an embodiment, the number of second-type photoelectric conversion elements PD2 included in the first set may be different from the number of second-type photoelectric conversion elements PD2 included in the second set. For example, the number of second-type photoelectric conversion elements PD2 included in the photoelectric conversion element group PDG may be ‘8’, the number of second-type photoelectric conversion elements PD2 included in the first set may be ‘3’, and the number of second-type photoelectric conversion elements PD2 included in the second set may be ‘5’.

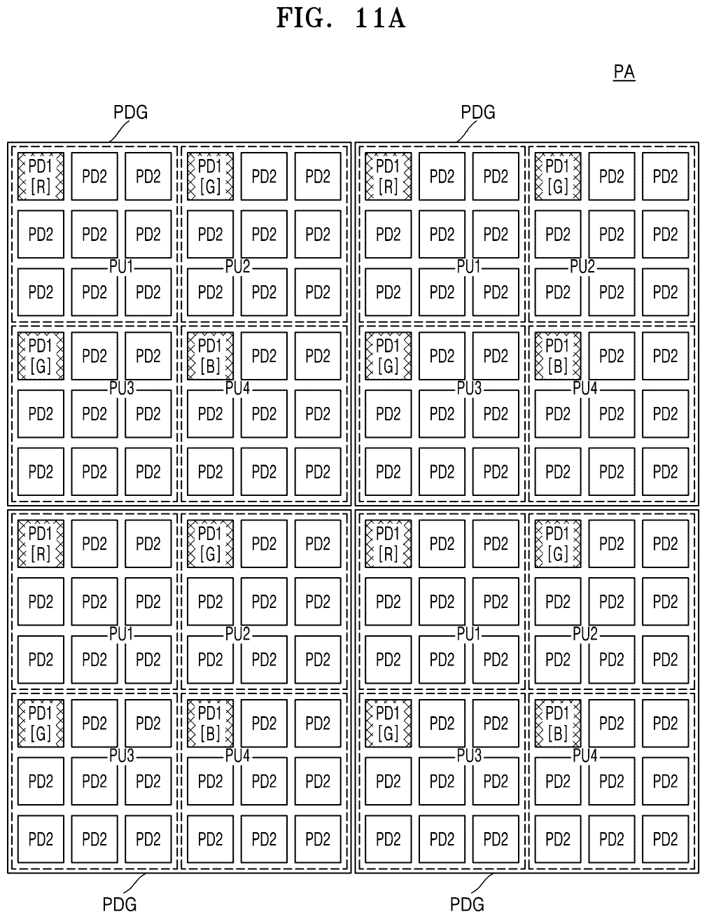

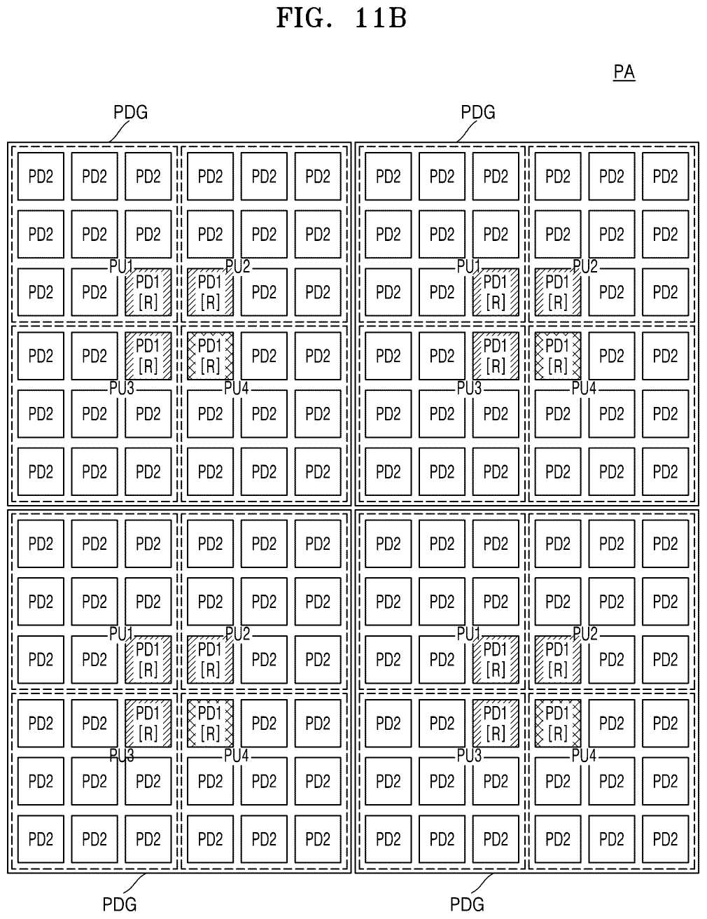

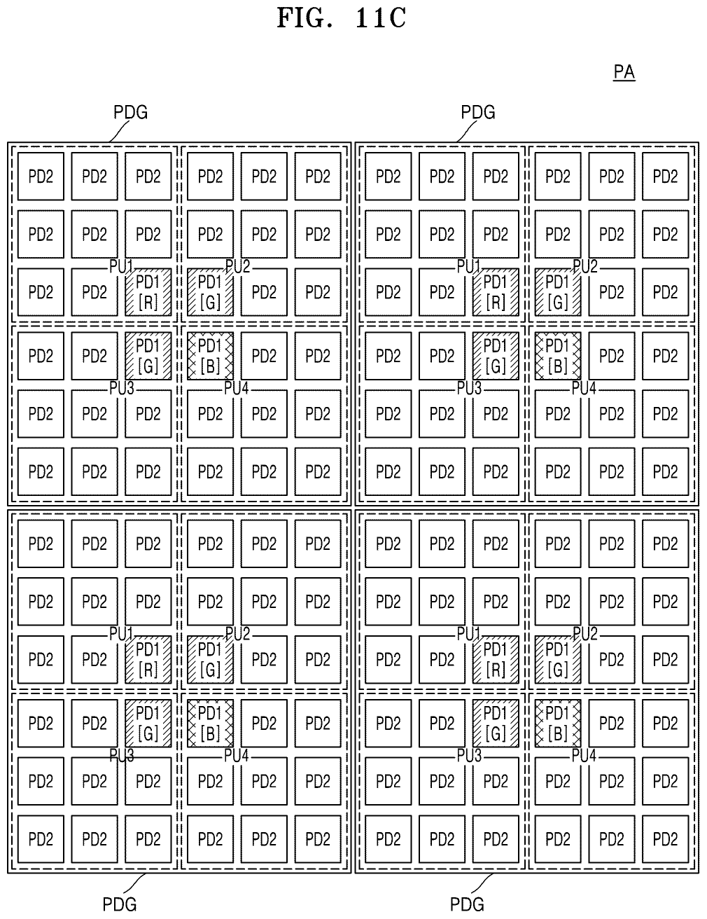

FIGS. 11A through 11C are diagrams illustrating an example of a photoelectric conversion element array according to an embodiment of the present disclosure.

Referring to FIGS. 11A, 11B, and 11C, the photoelectric conversion element array PA may include ‘144’ photoelectric conversion elements arranged in a 12×12 array (for example, 12 rows by 12 columns). The photoelectric conversion element array PA may include four photoelectric conversion element groups PDG arranged in a 2×2 array (for example, 2 rows by 2 columns). The photoelectric conversion element group PDG may include four the photoelectric conversion element units PU arranged in a 2×2 array (for example, 2 rows by 2 columns). Each of the photoelectric conversion element units PU may include ‘9’ photoelectric conversion elements arranged in a 3×3 array (for example, 3 rows by 3 columns).

In an embodiment, each of the photoelectric conversion element units PU may include M second-type photoelectric conversion elements PD2 and N first-type photoelectric conversion elements PD1. In this case, M and N may be natural numbers, and M may be greater than N. For example, M may be ‘8’, and N may be ‘1’. In each of the photoelectric conversion element units PU, the number of second-type photoelectric conversion elements PD2 may be greater than the number of first-type photoelectric conversion elements PD1.

In an embodiment, the positions of the first-type photoelectric conversion elements PD1 included in each of the photoelectric conversion element units PU included in the photoelectric conversion element group PDG may all be the same. The first-type photoelectric conversion element PD1 is disposed at one of the four corners of each photoelectric conversion element unit PU. Referring to FIG. 11A, in each of the photoelectric conversion element units PU, the first-type photoelectric conversion element PD1 may be arranged on the first row and the first column, the second-type photoelectric conversion element PD2 may be arranged on the first row and the second column, the second-type photoelectric conversion element PD2 may be arranged on the first row and the third column, the second-type photoelectric conversion element PD2 may be arranged on the second row and the first column, the second-type photoelectric conversion element PD2 may be arranged on the second row and the second column, the second-type photoelectric conversion element PD2 may be arranged on the second row and the third column, the second-type photoelectric conversion element PD2 may be arranged on the third row and the first column, the second-type photoelectric conversion element PD2 may be arranged on the third row and the second column, and the second-type photoelectric conversion element PD2 may be arranged on the third row and the third column.

In an embodiment, the first pixels PX1 included in the pixel group PG may be the same as or different from each other. The first pixels PX1 included in the pixel units PU may be of the same type or different types. For example, the first pixels PX1, corresponding to the first-type photoelectric conversion elements PD1 included in the photoelectric conversion element group PDG, may have a pixel structure of any one of RGGB, RCCC, RYYC, RGBC, RGBW, etc.

However, the scope of the inventive is not limited thereto, and the first pixels PX1, corresponding to the first-type photoelectric conversion elements PD1 of the photoelectric conversion element group PDG, may include the red R pixel, the green G pixel, the blue B pixel, a cyan C pixel, a yellow Y pixel, a magenta M pixel, a clear CL pixel, a white W pixel, or a combination thereof.

The photoelectric conversion element group PDG may have four first-type photoelectric conversion elements PD1. The photoelectric conversion element group PDG may include the first-type photoelectric conversion element PD1 corresponding to one red R pixel, the first-type photoelectric conversion elements PD1 corresponding to two green G pixels, and the first-type photoelectric conversion element PD1 corresponding to one blue B pixel. The first pixels PX1 corresponding to the first-type photoelectric conversion elements PD1 of the photoelectric conversion element group PDG may have an RGGB pixel structure. For example, the first-type photoelectric conversion element PD1 of a first photoelectric conversion element unit PU1 may correspond to the red R pixel, the first-type photoelectric conversion element PD1 of the second photoelectric conversion element unit PU2 may correspond to the green G pixel, the first-type photoelectric conversion element PD1 of the third photoelectric conversion element unit PU3 may correspond to the green G pixel, and the first-type photoelectric conversion element PD1 of the fourth photoelectric conversion element unit PU4 may correspond to the blue B pixel.

In an embodiment, the first-type photoelectric conversion element PD1 included in the photoelectric conversion element group PDG may not share the reset transistor, the driving transistor, and the selection transistor. The first pixel PX1, corresponding to the first-type photoelectric conversion element PD1 of each of the photoelectric conversion element unit PU, may include a unique reset transistor, a unique driving transistor, and a unique selection transistor.

In an embodiment, the first portion of the second-type photoelectric conversion element PD2 included in each of the photoelectric conversion element units PU may share the I/V converter 210, the amplifier circuit 220, and the comparator circuit 230 of the first DVS pixel unit circuit DUC1. The second portion of the second-type photoelectric conversion element PD2 included in each of the photoelectric conversion element units PU may share the I/V converter 210, the amplifier circuit 220, and the comparator circuit 230 of the second DVS pixel unit circuit DUC2.

For example, the first portion of the second-type photoelectric conversion element PD2 included in the first photoelectric conversion element unit PU1 may be referred to as the first set, and the second portion of the second-type photoelectric conversion element PD2 included in the first photoelectric conversion element unit PU1 may be referred to as the second set.

In an embodiment, the number of second-type photoelectric conversion elements PD2 included in the first set may be the same as the number of second-type photoelectric conversion elements PD2 included in the second set. For example, the number of second-type photoelectric conversion elements PD2 included in the first photoelectric conversion element unit PU1 may be ‘8’, the number of second-type photoelectric conversion elements PD2 included in the first set may be ‘4’, and the number of second-type photoelectric conversion elements PD2 included in the second set may be ‘4’.

In an embodiment, the number of second-type photoelectric conversion elements PD2 included in the first set may be different from the number of second-type photoelectric conversion elements PD2 included in the second set. For example, the number of second-type photoelectric conversion elements PD2 included in the first photoelectric conversion element unit PU1 may be ‘8’, the number of second-type photoelectric conversion elements PD2 included in the first set may be ‘3’, and the number of second-type photoelectric conversion element PD22 included in the second set may be ‘5’.

Referring to FIG. 11B, the positions of the first-type photoelectric conversion elements PD1 included in each of the photoelectric conversion element units PU included in the photoelectric conversion element group PDG may all be different from each other. In AN embodiment, the first-type photoelectric conversion element PD1 in a first photoelectric conversion element unit PU1 is directly adjacent to the first-type photoelectric conversion element PD1 in a second photoelectric conversion element unit PU2. The first photoelectric conversion element unit PU1 is directly adjacent to the second photoelectric conversion element unit PU2. The first-type photoelectric conversion elements may be disposed at the center portion of photoelectric conversion element group PDG.

For example, in the first photoelectric conversion element unit PU1, the first-type photoelectric conversion element PD1 may be arranged on the third row and the third column, and the second-type photoelectric conversion elements PD2 may be arranged on other positions. In the second photoelectric conversion element unit PU2, the first-type photoelectric conversion element PD1 may be arranged on the third row and the first column, and the second-type photoelectric conversion elements PD2 may be arranged on other positions. In the third photoelectric conversion element unit PU3, the first-type photoelectric conversion element PD1 may be arranged on the first row and the third column, and the second-type photoelectric conversion elements PD2 may be arranged on other positions. In the fourth photoelectric conversion element unit PU4, the first-type photoelectric conversion element PD1 may be arranged on the first row and the first column, and the second-type photoelectric conversion elements PD2 may be arranged on other positions.

For example, in the photoelectric conversion element group PDG, the first-type photoelectric conversion element PD1 may be arranged on the third row and the third column, the first-type photoelectric conversion element PD1 may be arranged on the third row and the fourth column, the first-type photoelectric conversion element PD1 may be arranged on the fourth row and the third column, and the first-type photoelectric conversion element PD1 may be arranged on the fourth row and the fourth column. Each of the first-type photoelectric conversion elements PD1 may be arranged at an edge portion where the photoelectric conversion element units PU meet. Each of the first-type photoelectric conversion elements PD1 may be arranged at the center portion of the photoelectric conversion element group PDG.

In an embodiment, the first pixels PX1, corresponding to the first-type photoelectric conversion elements PD1 included in the photoelectric conversion element group PDG, may be the same as each other. The first pixels PX1, corresponding to the first-type photoelectric conversion elements PD1 included in the photoelectric conversion element unit PU, may all be of the same type. Each of the first pixels PX1, corresponding to the first-type photoelectric conversion elements PD1 of the photoelectric conversion element group PDG, may include the red R pixel, the green G pixel, the blue B pixel, the cyan C pixel, the yellow Y pixel, the magenta M pixel, the clear CL pixel, or the white W pixel.

For example, each of the first-type photoelectric conversion elements PD1 included in the photoelectric conversion element group PDG may correspond to the red R pixel. For example, the first-type photoelectric conversion element PD1 included in the first photoelectric conversion element unit PU1 may correspond to the red R pixel, the first-type photoelectric conversion element PD1 included in the second photoelectric conversion element unit PU2 may correspond to the red R pixel, the first-type photoelectric conversion element PD1 included in the third photoelectric conversion element unit PU3 may correspond to the red R pixel, and the first-type photoelectric conversion element PD1 included in the fourth photoelectric conversion element unit PU4 may correspond to the red R pixel.

In an embodiment, the first-type photoelectric conversion element PD1 included in the photoelectric conversion element group PDG may not share the reset transistor, the driving transistor, and the selection transistor. The first pixel PX1, corresponding to the first-type photoelectric conversion element PD1 of each of the photoelectric conversion element unit PU, may include the reset transistors, the driving transistors, and the selection transistors, which are different from each other.

In an embodiment, the first-type photoelectric conversion element PD1 included in the photoelectric conversion element group PDG may share the reset transistor, the driving transistor, and the selection transistor. In addition, the first-type photoelectric conversion element PD1 of the photoelectric conversion element group PDG may share the floating diffusion area. In an embodiment, the first-type photoelectric conversion element PD1 of the photoelectric conversion element group PDG may further share the dual conversion transistor.

Referring to FIG. 11C, the first pixels PX1, corresponding to first-type photoelectric conversion elements PD1 included in the photoelectric conversion element group PDG, may be the same as or different from each other. The first pixels PX1, corresponding to first-type photoelectric conversion elements PD1 included in the photoelectric conversion element units PU1 through PU4, may be of the same type or different types. The photoelectric conversion element group PDG may have four first-type photoelectric conversion elements PD1. The photoelectric conversion element group PDG may include the first-type photoelectric conversion element PD1 corresponding to one red R pixel, the first-type photoelectric conversion elements PD1 corresponding to two green G pixels, and the first-type photoelectric conversion element PD1 corresponding to one blue B pixel. The first pixels PX1, corresponding to the first-type photoelectric conversion elements PD1 of the photoelectric conversion element group PDG, may have an RGGB pixel structure. For example, the first-type photoelectric conversion element PD1 of the first photoelectric conversion element unit PU1 may correspond to the red R pixel, the first-type photoelectric conversion element PD1 of the second photoelectric conversion element unit PU2 may correspond to the green G pixel, the first-type photoelectric conversion element PD1 of the third photoelectric conversion element unit PU3 may correspond to the green G pixel, and the first-type photoelectric conversion element PD1 of the fourth photoelectric conversion element unit PU4 may correspond to the blue B pixel.

For example, the first pixels PX1, corresponding to the first-type photoelectric conversion elements PD1 included in the photoelectric conversion element group PDG, may have a pixel structure of any one of RGGB, RCCC, RYYC, RGBC, RGBW, etc. However, the scope of the inventive is not limited thereto, and the first pixels PX1, corresponding to the first-type photoelectric conversion elements PD1 of the photoelectric conversion element group PDG, may include the red R pixel, the green G pixel, the blue B pixel, the cyan C pixel, the yellow Y pixel, the magenta M pixel, the clear CL pixel, the white W pixel, or a combination thereof.

While the inventive concept has been particularly shown and described with reference to embodiments thereof, it will be understood that various change in form and details may be made therein without departing from the spirit and scope of the following claims.

What is claimed is:

1. A vision sensor comprising:
a first semiconductor die comprising a plurality of photoelectric conversion element groups; and
a second semiconductor die comprising a dynamic vision sensor (DVS) pixel circuit and stacked on the first semiconductor die in a copper-to-copper bonding manner,
wherein each of the plurality of photoelectric conversion element groups comprises:
a first-type photoelectric conversion element configured to output an electrical signal corresponding to an amount of light incident on the first-type photoelectric conversion element, and
a plurality of second-type photoelectric conversion elements, each configured to output charges corresponding to an amount of light incident on the second-type photoelectric conversion element,
wherein the DVS pixel circuit is configured to output an event signal based on the charges generated by the plurality of second-type photoelectric conversion elements, and
wherein, in each of the plurality of photoelectric conversion element groups, a total number of second-type photoelectric conversion elements is greater than a total number of first-type photoelectric conversion elements.

2. The vision sensor of claim 1, further comprising:
a transmission transistor;
a reset transistor; and
a driving transistor corresponding to the first-type photoelectric conversion element in each of the plurality of photoelectric conversion element groups, and
wherein the transmission transistor, the reset transistor, and the driving transistor are disposed on the first semiconductor die.

3. The vision sensor of claim 2, wherein, in each of the plurality of photoelectric conversion element groups, the total number of second-type photoelectric conversion elements is more than twice the total number of first-type photoelectric conversion elements.

4. The vision sensor of claim 3, wherein the DVS pixel circuit comprises:
a logarithmic amplifier connected to at least one of the second-type photoelectric conversion elements; and
a feedback transistor connected to at least one of the second-type photoelectric conversion elements.

5. The vision sensor of claim 4, wherein, in each the plurality of photoelectric conversion element groups, the total number of second-type photoelectric conversion elements is more than three times the total number of first-type photoelectric conversion elements.

6. The vision sensor of claim 3, wherein, in each photoelectric conversion element group, relative positions of the first-type photoelectric conversion elements with respect to the photoelectric conversion element group are identical.

7. The vision sensor of claim 5, further comprising:
a third semiconductor die stacked on the second semiconductor die,
wherein the third semiconductor dies comprises a DVS logic and an analog to digital converter.

8. The vision sensor of claim 5, wherein, in each the plurality of photoelectric conversion element groups, the total number of second-type photoelectric conversion elements is more than four times the total number of first-type photoelectric conversion elements.

9. The vision sensor of claim 5, wherein each of the plurality of photoelectric conversion element groups comprises a plurality of photoelectric conversion elements arranged in N rows and M columns,
wherein the first-type photoelectric conversion element is disposed at one of four corners formed by an array of N rows and M columns, and
wherein N and M are integers.

10. The vision sensor of claim 5, wherein, the first-type photoelectric conversion elements in a first photoelectric conversion element group is directly adjacent to the first-type photoelectric conversion elements in a second photoelectric conversion element group, and
wherein the first photoelectric conversion element group is directly adjacent to the second photoelectric conversion element group.

11. The vision sensor of claim 5, wherein each of the plurality of photoelectric conversion element groups comprises a plurality of photoelectric conversion elements arranged in N rows and M columns,
wherein the first-type photoelectric conversion element is disposed at a center portion of an array of N rows and M columns, and
wherein N and M are integers.

12. The vision sensor of claim 7, wherein the first-type photoelectric conversion element of the plurality of photoelectric conversion element groups shares a reset transistor, a driving transistor, and a selection transistor.

13. A vision sensor comprising:
a first semiconductor die comprising a first-type photoelectric conversion element and a second-type photoelectric conversion element; and
a second semiconductor die comprising a dynamic vision sensor (DVS) pixel circuit, a selection transistor, and a driving transistor corresponding to the first-type photoelectric conversion element,
wherein the first-type photoelectric conversion element is configured to output an electrical signal corresponding to an amount of light incident on the first-type photoelectric conversion element,
wherein the second-type photoelectric conversion element is configured to output charges corresponding to an amount of light incident on the second-type photoelectric conversion element,
wherein the DVS pixel circuit is configured to output an event signal based on charges generated by the second-type photoelectric conversion element,
wherein the first semiconductor die is connected to the second semiconductor die in a copper-to-copper bonding manner, and
wherein, a total number of second-type photoelectric conversion elements is greater than a total number of first-type photoelectric conversion elements.

14. The vision sensor of claim 13, wherein the total number of photoelectric conversion elements in a first photoelectric conversion element group is identical to the total number of a second-type photoelectric conversion elements in a second photoelectric conversion element group.

15. The vision sensor of claim 13, wherein the total number of second-type photoelectric conversion elements in the first photoelectric conversion element group is different than the total number of second-type photoelectric conversion elements in the second photoelectric conversion element group.

16. The vision sensor of claim 13, wherein, in each the plurality of photoelectric conversion element groups, the total number of second-type photoelectric conversion elements is more than twice the total number of first-type photoelectric conversion elements.

17. The vision sensor of claim 13, wherein the DVS pixel circuit comprises:
a logarithmic amplifier connected to at least one of the second-type photoelectric conversion elements; and
a feedback transistor connected to at least one of the second-type photoelectric conversion elements.

18. The vision sensor of claim 17, further comprising:
a third semiconductor die stacked on the second semiconductor die,
wherein the third semiconductor dies comprises a DVS logic and an analog to digital converter.

19. A vision sensor comprising:
a first semiconductor die comprising a plurality of photoelectric conversion element groups;
a second semiconductor die comprising a dynamic vision sensor (DVS) pixel circuit and stacked on the first semiconductor die in a copper-to-copper bonding manner; and
a third semiconductor die comprising a complementary metal-oxide semiconductor image sensor (CIS) logic and a DVS logic,
wherein each of the plurality of photoelectric conversion element groups comprises:
a first-type photoelectric conversion element configured to output an electrical signal corresponding to an amount of light incident on the first-type photoelectric conversion element; and
a plurality of second-type photoelectric conversion elements, each configured to output charges corresponding to an amount of light incident on the second-type photoelectric conversion element,
wherein the DVS pixel circuit is configured to output an event signal based on charges generated by the plurality of second-type photoelectric conversion elements,
wherein, in each the plurality of photoelectric conversion element groups, a total number of second-type photoelectric conversion elements is greater than a total number of first-type photoelectric conversion elements, and
wherein the third semiconductor die is stacked on the second semiconductor die.

20. The vision sensor of claim 19, wherein the first semiconductor die further comprises:
a reset transistor;
a driving transistor; and
a selection transistor,
wherein the reset transistor, driving transistor, and the selection transistor are shared by a plurality of first-type photoelectric conversion elements in a first photoelectric conversion element group.
